(19) United States
(12) Patent Application Publication
(10) Pub. No.: US 2025/0374835 A1
(43) Pub. Date: Dec. 4, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Chi-Hung LU, Hsinchu (TW); Huan-Chieh CHEN, Taichung (TW)

(21) Appl. No.: 18/676,649

(22) Filed: May 29, 2024

(51) Int. Cl. H10N 70/20; H01L 23/66; H10B 63/10; H10N 70/00

(52) U.S. Cl. CPC H10N 70/231; H01L 23/66; H10B 63/10; H10N 70/021; H10N 70/063; H10N 70/841; H10N 70/8613; H10N 70/882; H01L 2223/6661

(57) ABSTRACT

Some implementations described herein include a semiconductor device. The semiconductor device includes a radio frequency switch structure including a phase change material layer and a heat spreader component. A form factor and a location of the heat spreader component improves a uniformity of heat distribution within the radio frequency switch structure relative to other heat spreader components having different form factors and/or locations. Additionally, the phase change material layer includes a concentration of germanium and tellurium that reduces a resistivity of the radio frequency switch structure relative to other concentrations.

### BACKGROUND

A radio frequency (RF) switch structure may be implemented using complementary metal oxide semiconductor (CMOS) manufacturing processes. An example of an RF switch structure includes a phase change material (PCM) RF switch structure. A PCM RF switch structure is an RF switch structure that selectively transitions (or switches) between an “on” state and an “off” state by selectively changing a phase of a PCM layer (e.g., a layer of PCM) of the PCM RF switch structure between a crystalline phase and an amorphous phase. In the on state, an RF signal is permitted to flow through the switching material of the RF switch structure between an input and an output. In the off state, the RF signal is restricted from flowing through the channel.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2D are diagrams of example implementations of an example semiconductor device described herein.

FIGS. 3A-3C are diagrams of example implementations of operation of a radio frequency switch structure described herein.

FIGS. 4A-4E are diagrams of an example implementation of a radio frequency switch structure described herein.

FIGS. 5A-5M are diagrams of an example implementation of forming a semiconductor device described herein.

FIGS. 6A and 6B are diagrams of example data related to an implementation of a radio frequency switch structure described herein.

FIG. 7 is a diagram of example data related to an implementation of a radio frequency switch structure described herein.

FIG. 8 is a diagram of example components of a device described herein.

FIG. 9 is a flowchart of an example process associated with forming a semiconductor device described herein.

FIGS. 10A and 10B are diagrams of example implementations of a radio frequency switch structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A radio frequency (RF) switch is an electronic device used in RF and microwave systems to selectively route or connect RF signals between different paths or components. RF switch structures are designed to handle high-frequency signals and are commonly used in various applications, including telecommunications, wireless communication systems, radar systems, test and measurement equipment, and more. The RF switch structure may include a phase change material (PCM) that changes between a crystalline phase and an amorphous phase as part of a switching operation that manages RF signals by providing options for signal routing, isolation, and control.

Figure of Merit (FOM) and cycling endurance are indices that may indicate a performance quality and a reliability of the RF switch structure in an RF device. In some cases, a concentration of elements included in the PCM material layer (e.g., molar percentages of the elements included in the PCM material layer) may adversely increase a resistivity of the RF switch structure to decrease the FOM of the RF switch structure relative to other concentrations of the elements. Additionally, or alternatively, nonuniform heat dissipation within the RF device (e.g., differences in dissipation between edges and a center of the RF switch structure) may increase stresses and/or strains within the RF switch structure that degrades a cycling endurance of the RF switch structure.

Some implementations described herein include a semiconductor device. The semiconductor device includes an RF switch structure including a phase change material (PCM) layer and a heat spreader component. A form factor and a location of the heat spreader component improves a uniformity of heat distribution within the semiconductor device relative to other heat spreader components having different form factors and/or locations. Additionally, the PCM layer includes a concentration of germanium and tellurium that reduces a resistivity of the RF switch structure relative to other concentrations.

In this way, cycling endurance and FOM performances of the RF switch structure are increased relative to other RF switch structures. By increasing the cycling endurance and FOM performances, the semiconductor device may satisfy performance thresholds and have a reliability that reduces an amount of resources (e.g., raw materials, semiconductor processing equipment, labor, and/or computing resources) needed to service a high performance market using the semiconductor device.

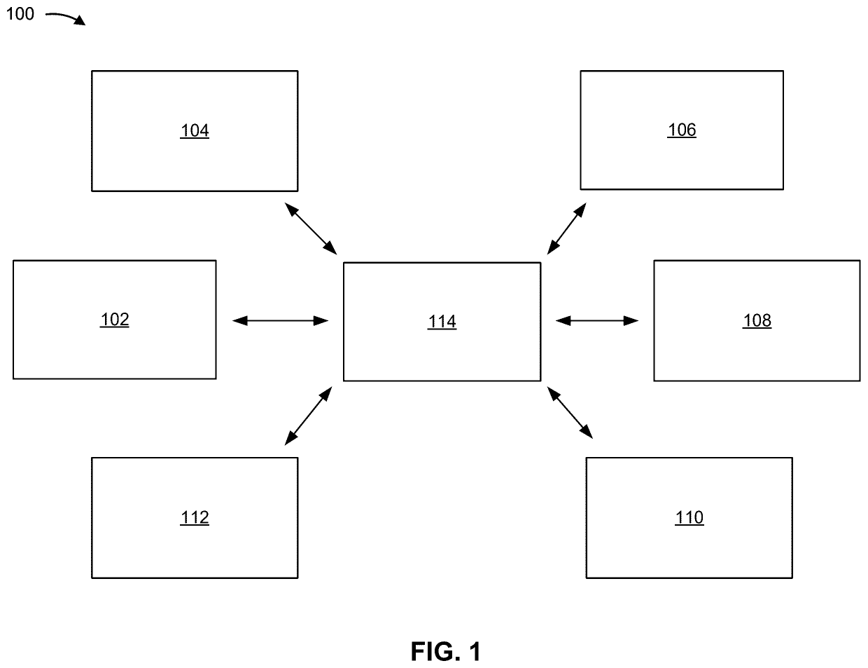

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-112 and/or the wafer/die transport tool 114 may be used to perform a series of semiconductor processing operations described herein. For example, the series of semiconductor processing operations includes forming a heat spreader component of a switch structure in a first dielectric layer, where the heat spreader component has a first length. The series of semiconductor processing operations includes forming a second dielectric layer above the first dielectric layer. The series of semiconductor processing operations includes forming an input electrode of the switch structure and an output electrode of the switch structure in the second dielectric layer, where a length of the input electrode and the output electrode is less than or equal to the first length.

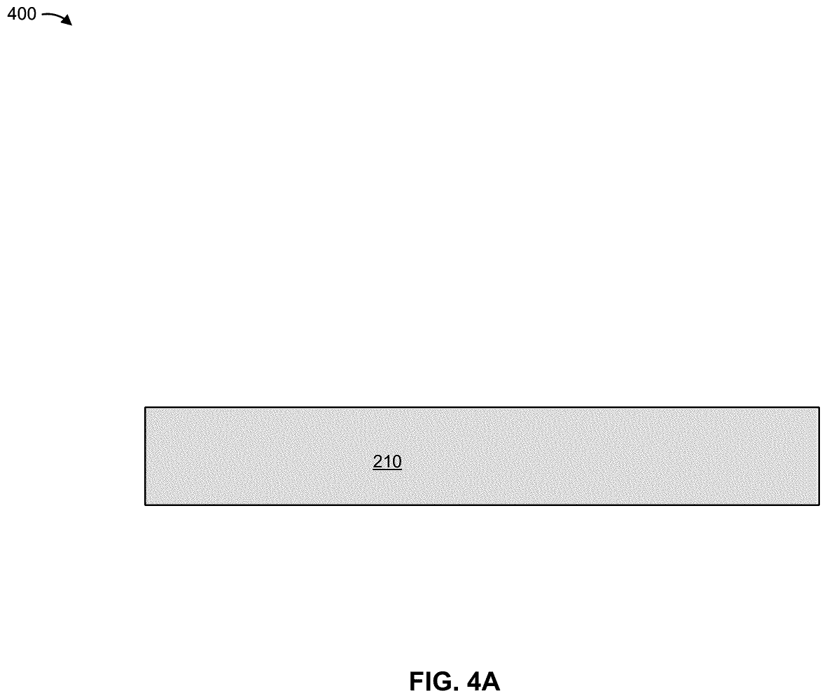

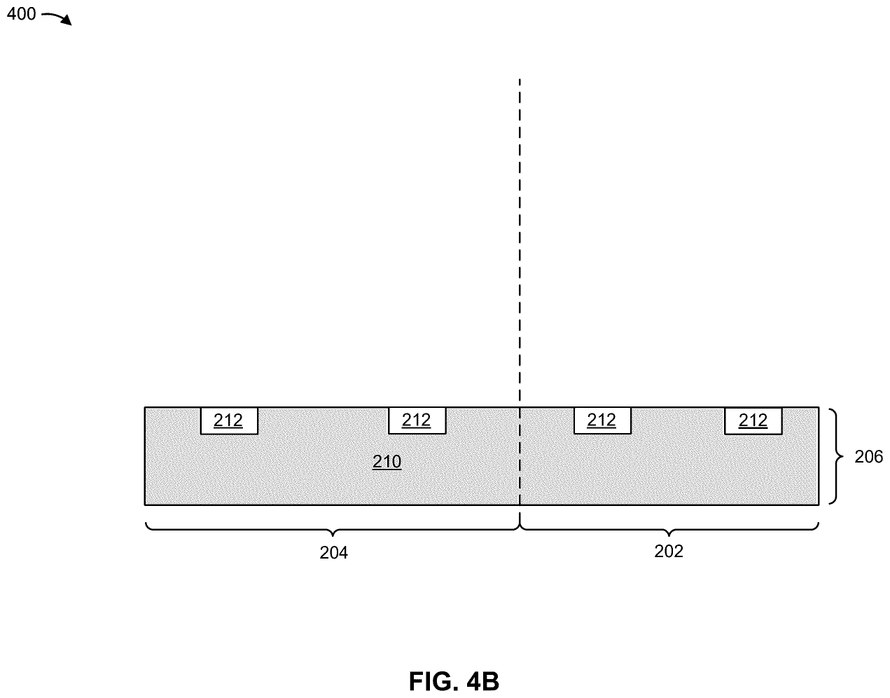

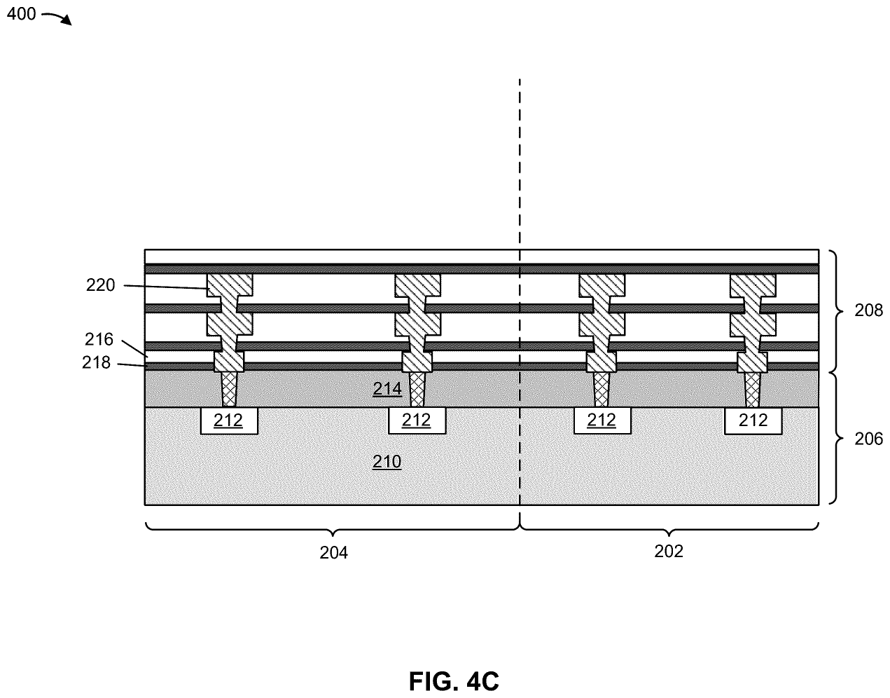

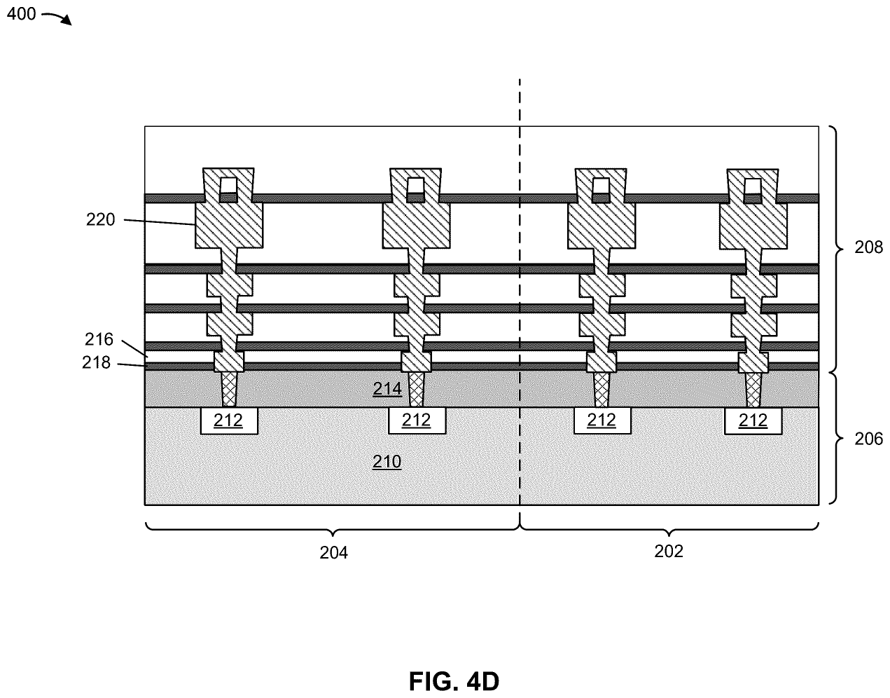

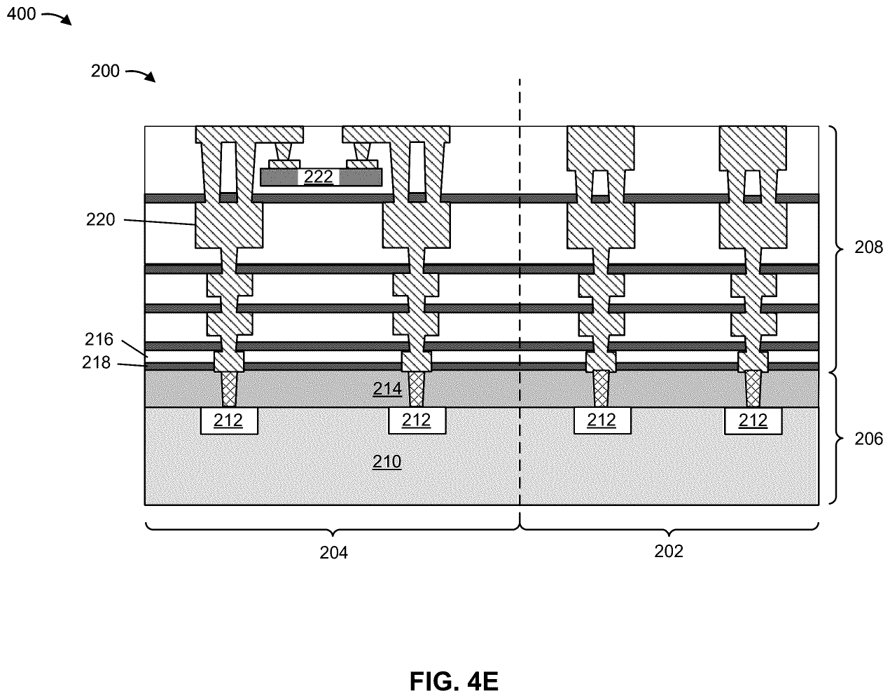

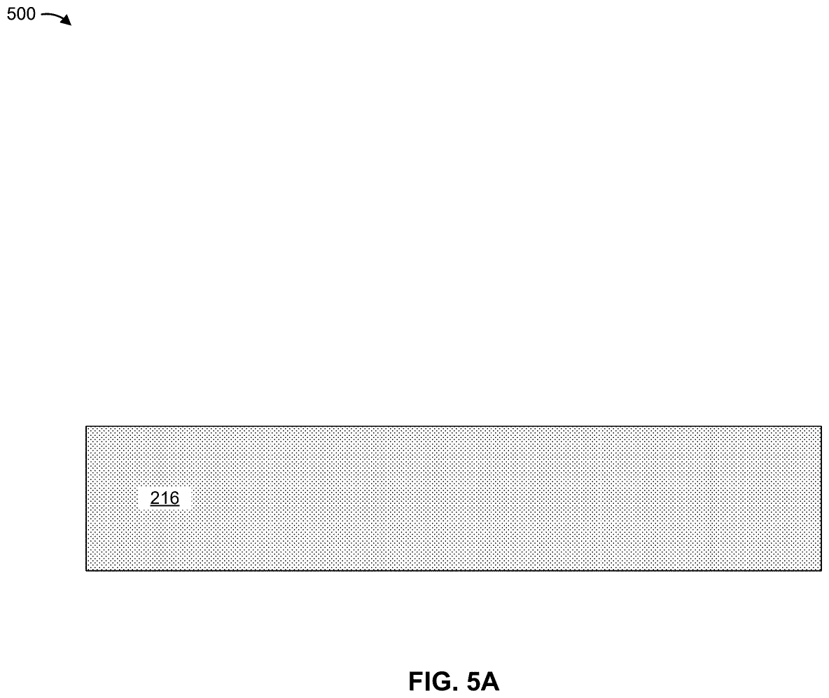

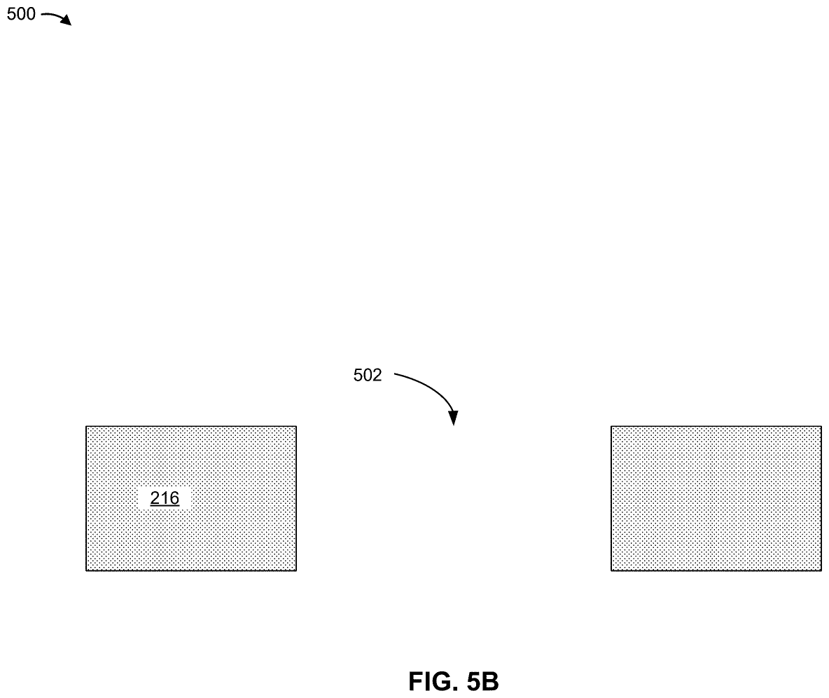

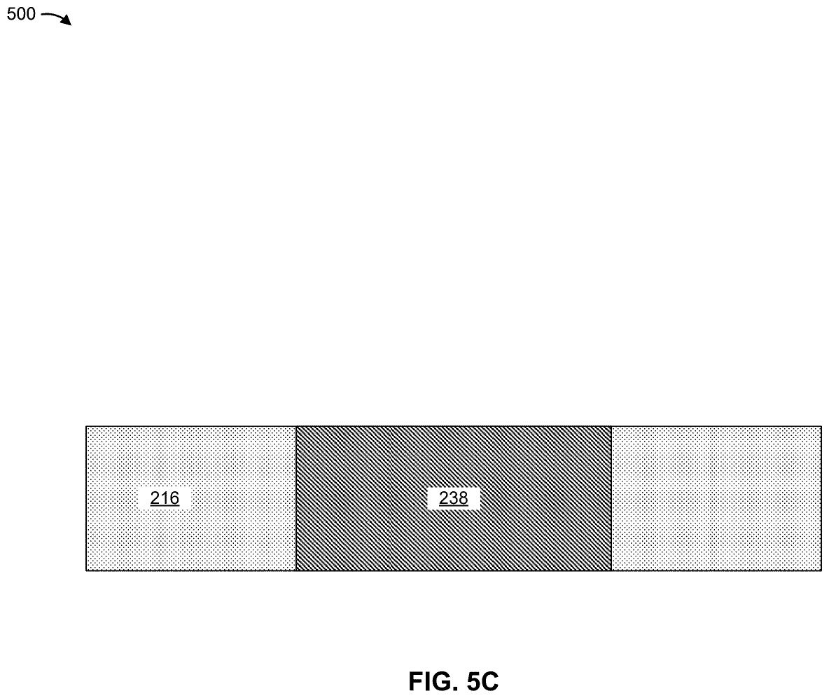

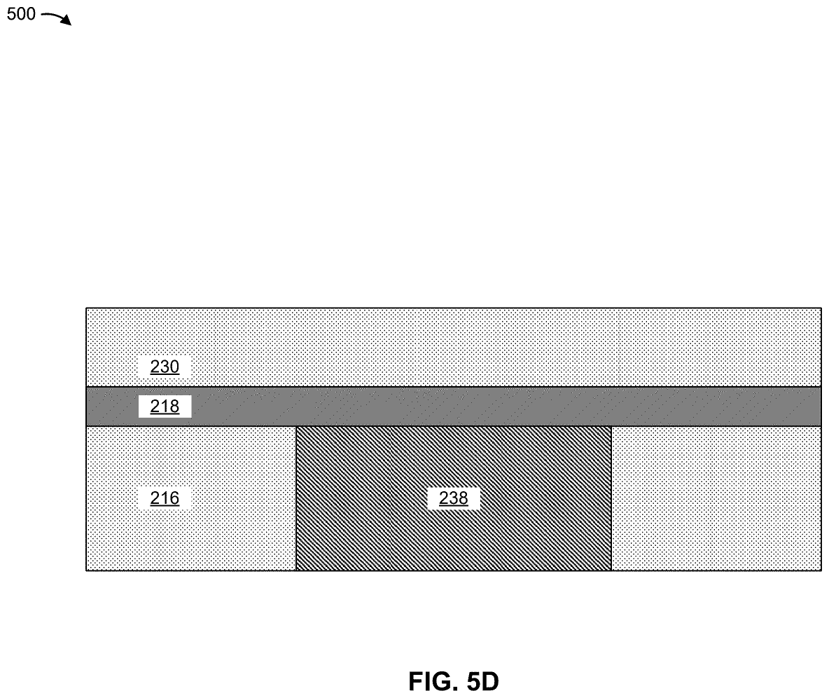

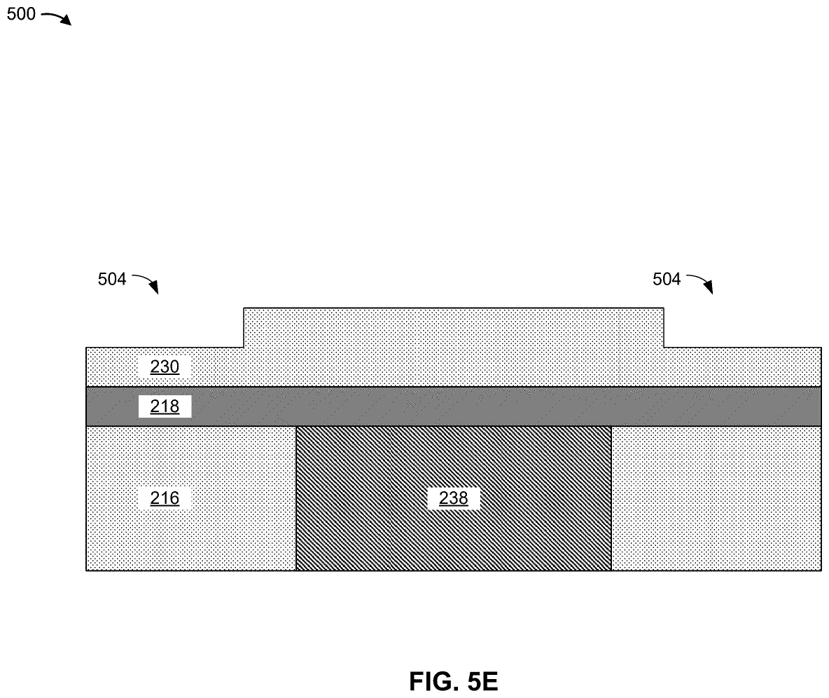

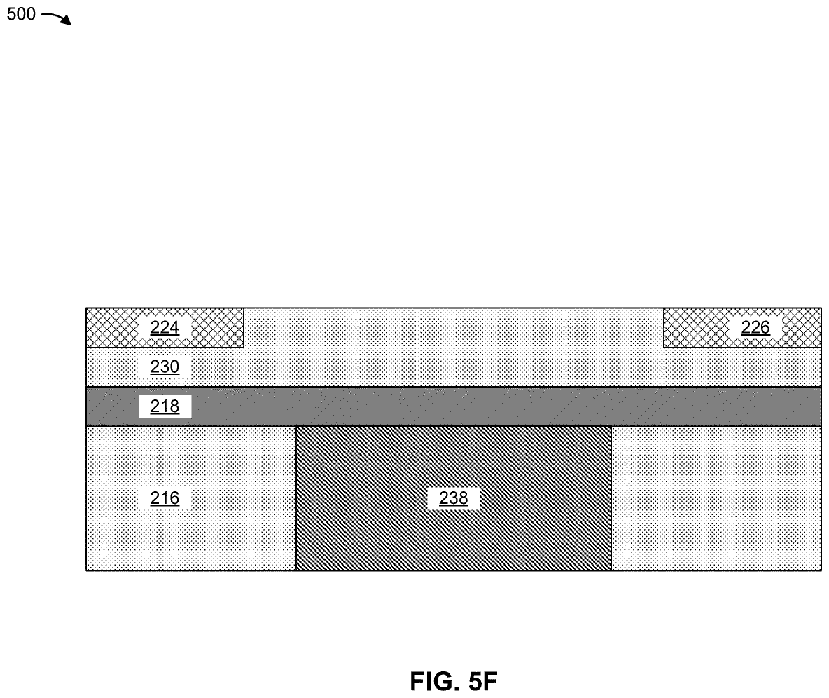

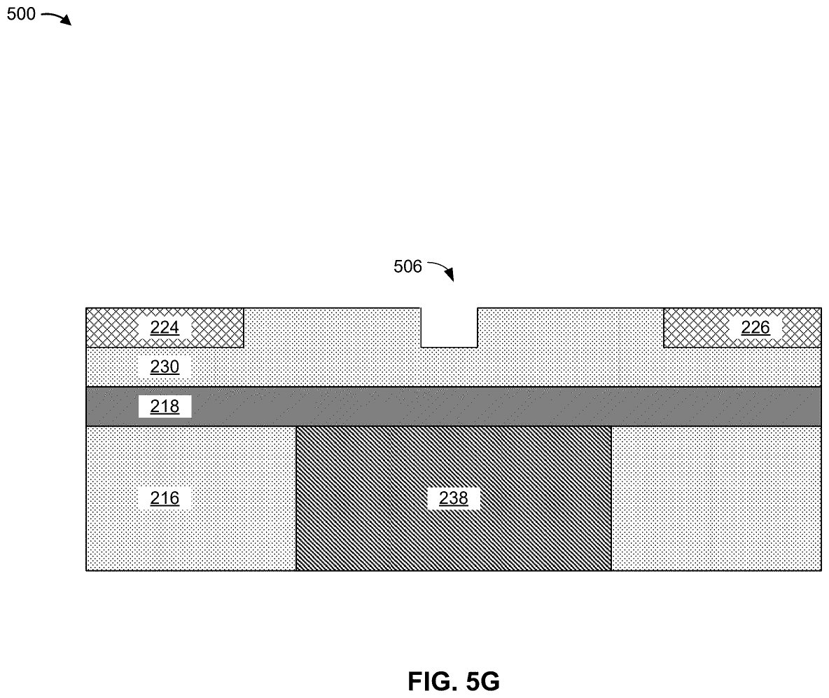

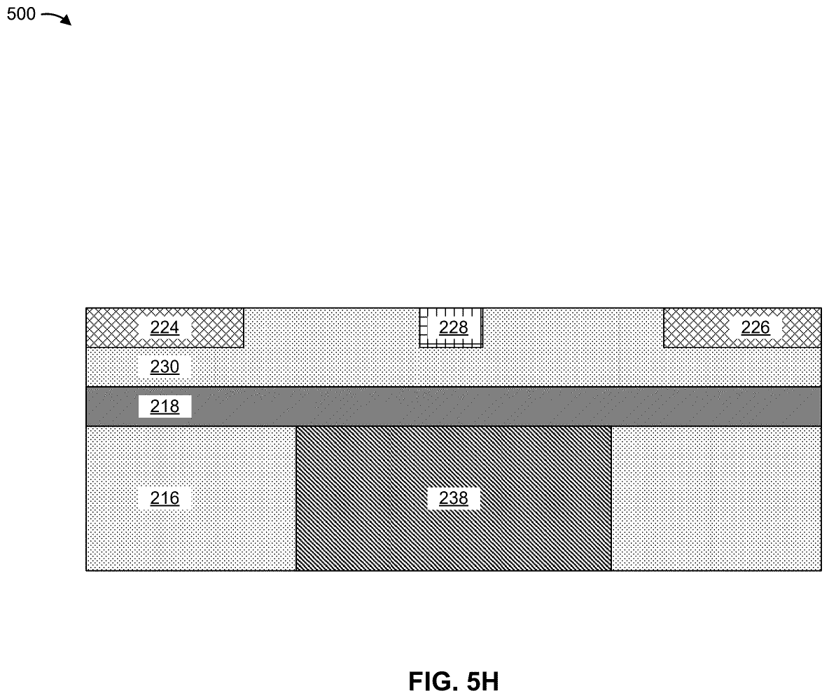

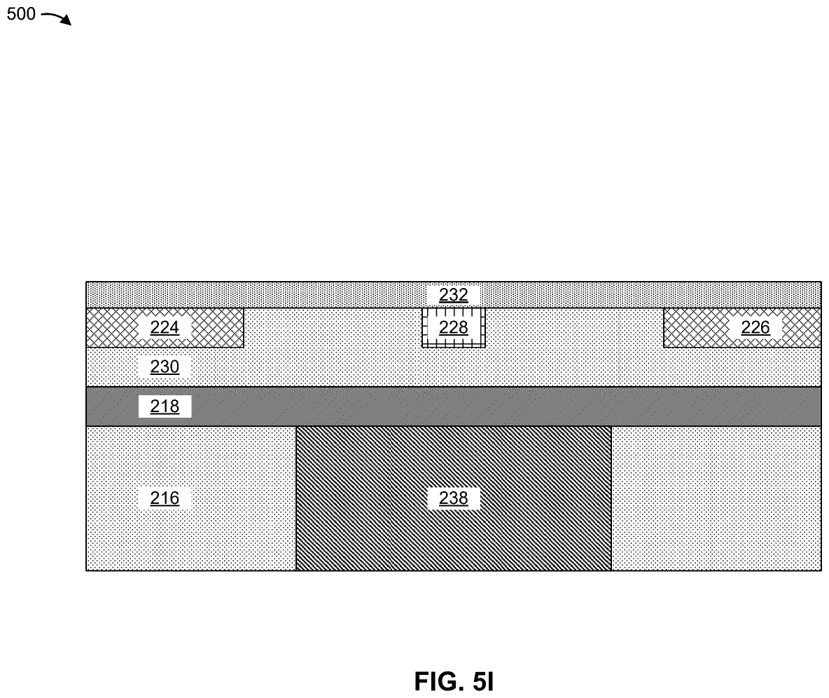

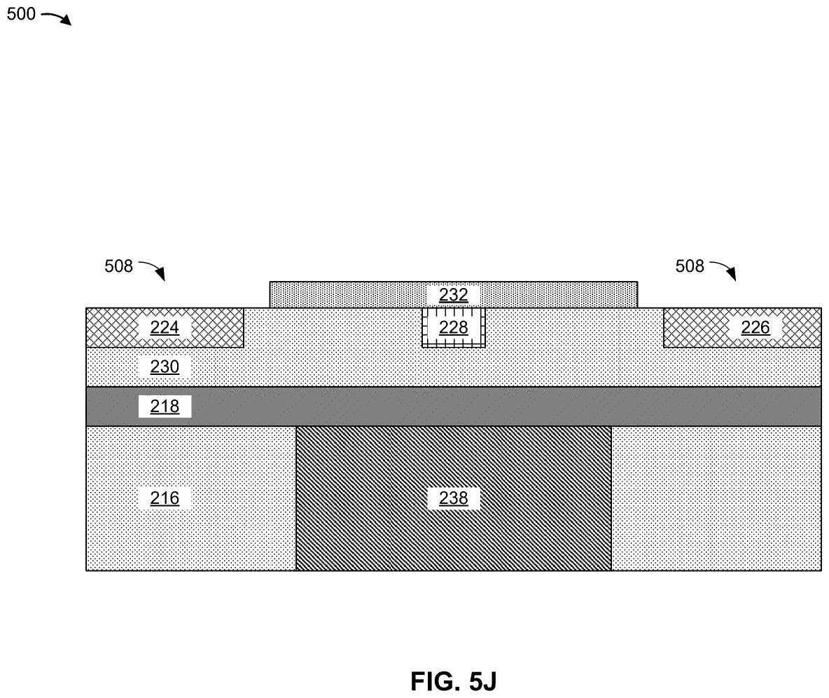

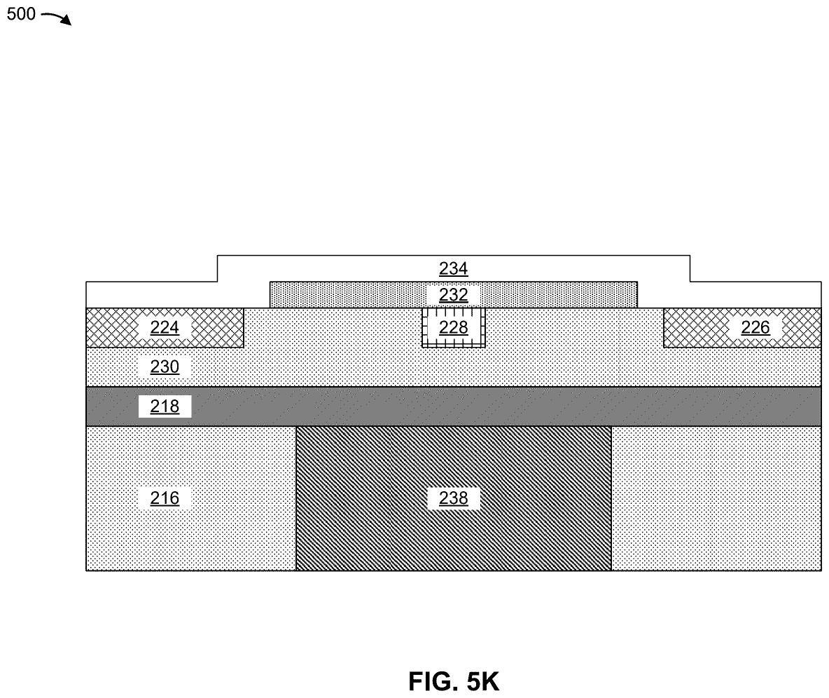

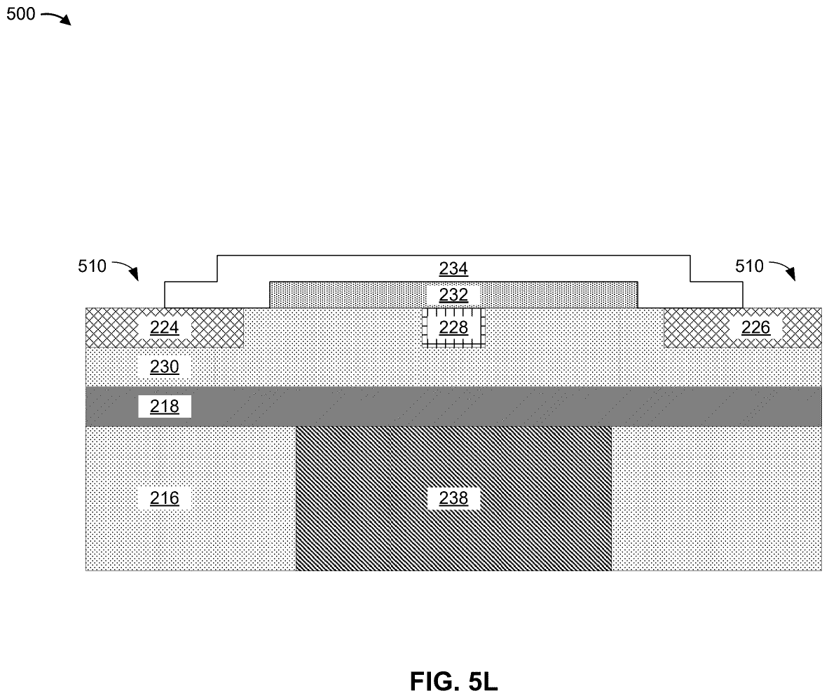

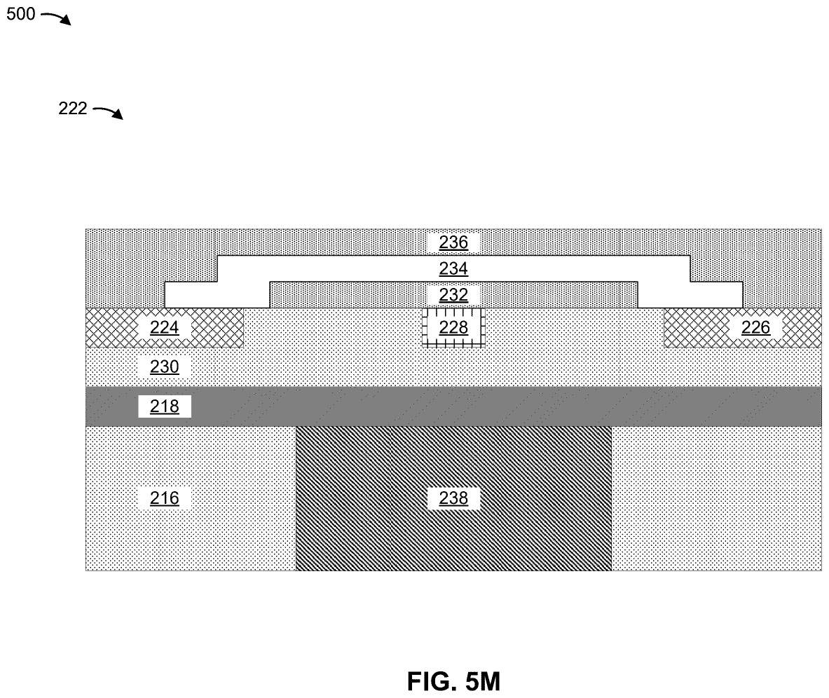

In some implementations, one or more of the semiconductor processing tools 102-112 and/or the wafer/die transport tool 114 may be used to perform one or more semiconductor processing operations described in connection with FIGS. 4A-4E, 5A-5M, and/or 9, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

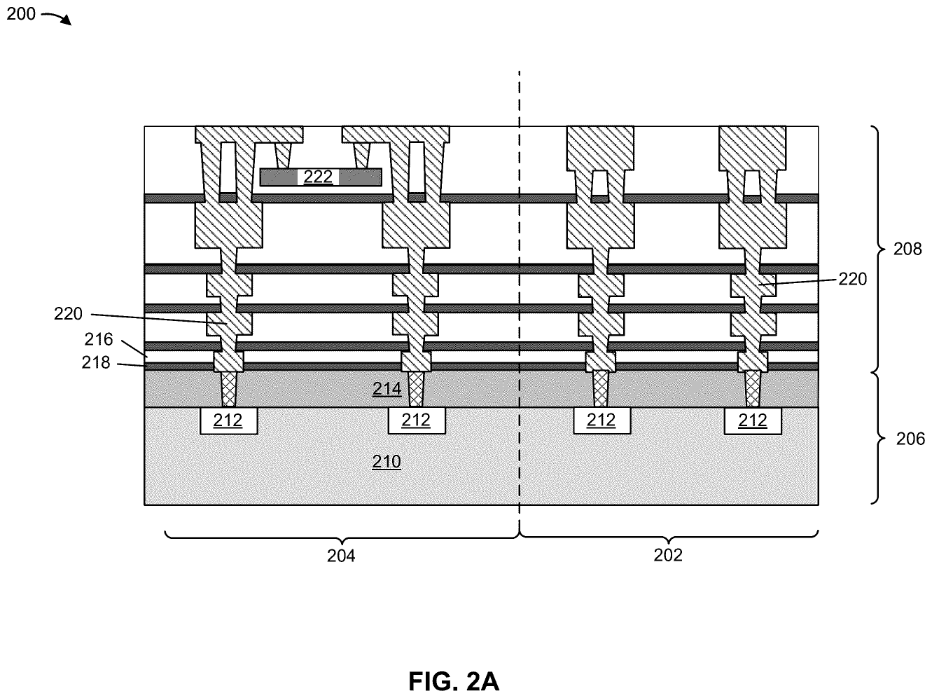

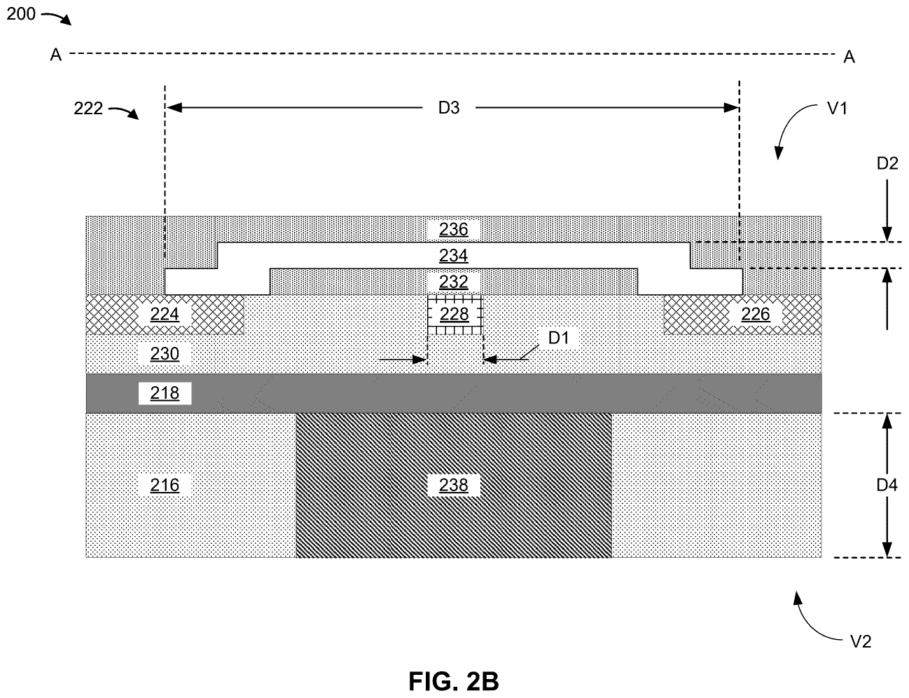

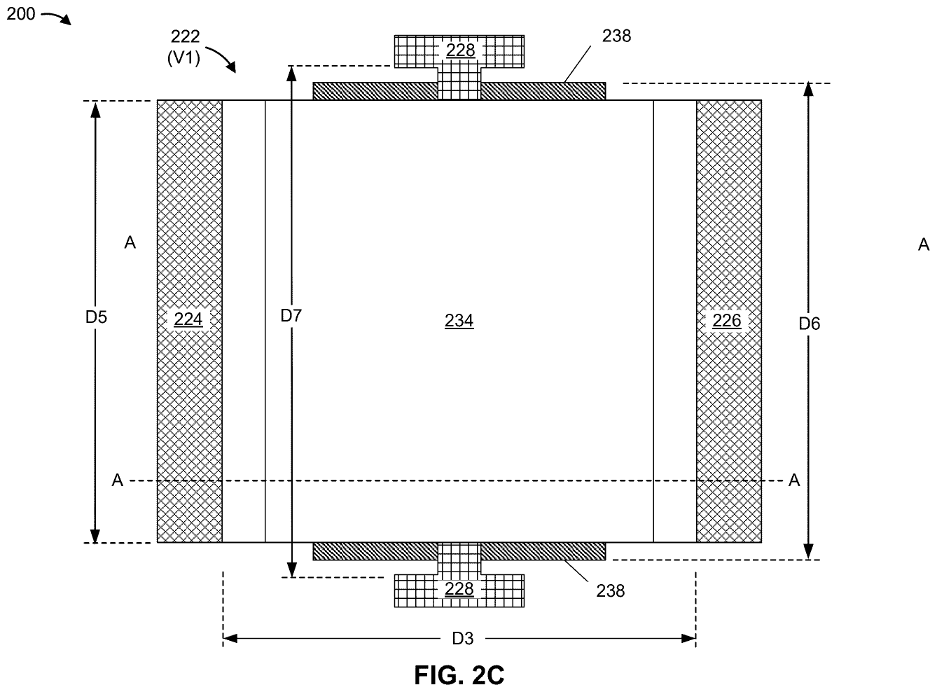

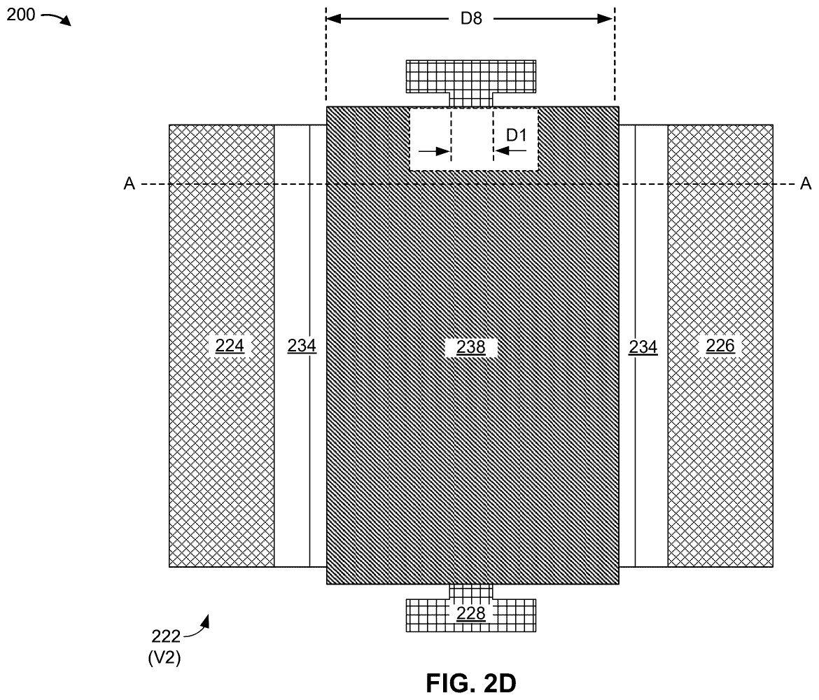

FIGS. 2A-2D are diagrams of example implementations of an example semiconductor device 200 described herein. In some implementations, the semiconductor device 200 includes a monolithic system on chip (SoC) die that includes a plurality of different functionalities, such as an RF front-end device, a baseband device, and/or another type of wireless communication device. In some implementations, the semiconductor device 200 includes a chiplet, which is a type of semiconductor die that includes a specific subset of functionalities of an overall semiconductor device package. For example, an RF front-end device may include a plurality of chiplets that are packaged on a semiconductor package substrate. A chiplet may correspond to a power amplifier die, a filter die, an RF switch structure die, an antenna switch die, and/or an antenna tuner die, among other examples. The chiplets may be electrically connected through redistribution layers in the semiconductor package substrate, and/or may be stacked in a system on integrated chips (SoIC) manner such that two or more chiplets are directly bonded and interconnected. Implementing chiplets on a semiconductor package substrate (e.g., as opposed to a monolithic die that includes the entire suite of functionalities) enables advancements to be realized for specific functionalities without having to necessarily redesign semiconductor dies for other functionalities.

As shown in an example implementation of the semiconductor device 200 in FIG. 2A, the semiconductor device 200 includes a logic portion 202 and an RF portion 204 adjacent to the logic portion 202. The logic portion 202 includes logic circuitry of the semiconductor device 200, such as digital processing circuitry, complementary metal oxide semiconductor (CMOS) logic circuitry, and/or other types of logic circuitry. The RF portion 204 includes RF circuitry configured for processing of RF signals. In some implementations, the RF portion 204 includes circuitry configured for processing high-frequency and/or high-bandwidth RF signals, such as signals in the gigahertz (GHz) frequency range or greater (e.g., 60 GHz and greater). In some implementations, the RF portion 204 also includes other types of active devices (e.g., transistors) in addition to the RF circuitry.

As further shown in FIG. 2A, the semiconductor device 200 may include a frontend region 206 (e.g., a front end of line (FEOL) region) and a backend region 208 (e.g., a back end of line (BEOL) region). The frontend region 206 includes the substrate 210 and a plurality of active devices 212 that are included in and/or on the substrate 210. The active devices 212 include transistors (e.g., planar transistors, fin field effect transistors (finFETs), gate all around (GAA) transistors), pixel sensors, photodetectors, transceivers, transmitters, receives, optical circuits, and/or other types of semiconductor devices.

A dielectric layer 214 is included over the substrate 210. The dielectric layer 214 includes an ILD layer, an etch stop layer (ESL), and/or another type of dielectric layer. The dielectric layer 214 includes dielectric material(s) that enable various portions of the substrate 210 and/or the active devices 212 to be selectively etched or protected from etching, and/or to electrically isolate the active devices 212 in the frontend region 206. The dielectric layer 214 includes a silicon nitride (SiₓN_{y}), an oxide (e.g., a silicon oxide (SiOₓ) and/or another oxide material), and/or another type of dielectric material.

The backend region 208 is included above the substrate 210 and above the active devices 212. The dielectric layers may include dielectric layers 216 and ESLs 218 that are arranged in an alternating manner. The dielectric layers 216 the ESLs 218 may be arranged in a direction that is approximately perpendicular to the substrate 210. The dielectric layers 216 may each include an oxide (e.g., a silicon oxide (SiOₓ) and/or another oxide material), an undoped silicate glass (USG), a boron-containing silicate glass (BSG), a fluorine-containing silicate glass (FSG), and/or another suitable dielectric material. In some implementations, a dielectric layer 216 includes an ELK dielectric material having a dielectric constant that is less than approximately 2.5. The ESLs 218 may each include a silicon nitride (SiₓN_{y}), silicon carbide (SiC), silicon oxynitride (SiON), and/or another suitable dielectric material. In some implementations, a dielectric layer 216 and an ESL 218 include different dielectric materials to provide etch selectivity to enable various structures to be formed in the backend region 208.

The backend region 208 includes a plurality of metallization layers 220. The metallization layers 220 are electrically coupled and/or physically coupled with one or more of the active devices 212 in the frontend region 206. The metallization layers 220 correspond to circuitry that enables signals and/or power to be provided to and/or from the active devices 212. The metallization layers 220 each include vias, trenches, contacts, plugs, interconnects, and/or other types of conductive structures. The metallization layers 220 each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

In some implementations, the metallization layers 220 of the backend region 208 may be arranged in in a vertical manner. In other words, a plurality of stacked metallization layers 220 extend between the frontend region 206 and a top of the backend region 208 to facilitate electrical signals and/or power to be routed between the frontend region 206 and the top of the backend region 208. The plurality of stacked metallization layers 220 may be referred to as M-layers. For example, a metal-0 (M0) layer may be located at the bottom of the backend region 208 and may be directly coupled with the frontend region 206 (e.g., with the contacts or interconnects of the active devices 212 in the frontend region 206), a metal-1 layer (M1) layer may be located above the M0 layer in the backend region 208, a metal-2 layer (M2) layer may be located above the M1 layer, and so on. In some implementations, the backend region 208 includes nine (9) stacked metallization layers 220 (e.g., M0-M8). In some implementations, the backend region 208 includes another quantity of stacked metallization layers 220.

The backend region 208 includes an RF switch structure 222 in the RF portion 204. In some implementations, backend region 208 includes other active devices 212, such as a BEOL memory device, a BEOL resistor, a BEOL capacitor, and/or an optical modulator, among other examples, in the logic portion 202 of the semiconductor device 200.

FIG. 2B illustrates a detailed cross-section side view of the RF switch structure 222. The cross-section side view is along section line A-A that is used in connection with FIGS. 2C and 2D. FIG. 2B also includes reference perspective V1 (a top view perspective) used in connection with FIG. 2C and reference perspective V2 (a bottom view perspective) used in connection with FIG. 2D.

The RF switch structure 222 is an RF switch structure that operates at high frequencies by selectively transitioning (or switching) between an “on” state and an “off” state. The RF switch structure 222 may include a phase change material (PCM) RF switch structure (PCM-RFS) that switches between the on state and the off state by selectively changing a phase of a switching material of the RF switch structure 222 between a crystalline phase and an amorphous phase.

The RF switch structure 222 includes the dielectric layer 216 in the RF portion 204 of the backend region 208 of the semiconductor device 200. The dielectric layer 216 may include an oxide (e.g., a silicon oxide (SiOₓ) and/or another oxide material), an undoped silicate glass (USG), a boron-containing silicate glass (BSG), a fluorine-containing silicate glass (FSG), and/or another suitable dielectric material.

The RF switch structure 222 further includes the ESL 218 in the RF portion 204 of the backend region 208 of the semiconductor device 200. The ESL 218 may include a silicon nitride (SiₓN_{y}), silicon carbide (SiC), silicon oxynitride (SiON), and/or another suitable dielectric material.

The RF switch structure 222 further includes an RF in electrode 224, an RF out electrode 226, and a heater element 228 between the RF in electrode 224 and the RF out electrode 226. The RF in electrode 224 and the RF out electrode 226 may be spaced apart by a distance such that RF signals traverse through the PCM layer 234 between the RF in electrode 224 and the RF out electrode 226. The RF in electrode 224 and the RF out electrode 226 may each include one or more conductive materials to enable the RF in electrode 224 and the RF out electrode 226 to conduct RF signals (which may include time-varying electrical signals). Examples of conductive materials include tungsten (W), copper (Cu), cobalt (Co), titanium (Ti), aluminum (Al), ruthenium (Ru), a metal alloy, another conductive metal, and/or another suitable material.

The heater element 228 includes a region of material that is configured to conduct heat. The heater element 228 may include a conductive material having a low Seebeck coefficient and a high melting point (e.g., approximately equal to or greater than 1500 degrees Celsius) such as tungsten (W) or molybdenum (Mo), among other examples.

In some implementation, a central portion of the heater element 228 includes a width D1. As an example, the width D1 of the central portion of the heater element 228 may be included in a range of approximately 0.5 μm to 3.0 μm. However, other values and ranges for the width D1 are within the scope of the present disclosure.

The RF in electrode 224, the RF out electrode 226, and the heater element 228 are thermally isolated and/or electrically isolated by a dielectric fill layer 230 that extends across the RF portion 204 and the logic portion 202 of the semiconductor device 200. The dielectric fill layer 230 may include an oxide (e.g., a silicon oxide (SiOₓ) and/or another oxide material), an undoped silicate glass (USG), a boron-containing silicate glass (BSG), a fluorine-containing silicate glass (FSG), and/or another suitable dielectric material.

The RF switch structure 222 further includes a layer stack over and/or on the RF in electrode 224, the RF out electrode 226, the heater element 228, and/or the dielectric fill layer 230. The layer stack includes a dielectric layer 232 on and/or over the heater element 228, a PCM layer 234 on and/or over the dielectric layer 232, and a dielectric layer 236 on and/or over the PCM layer 234.

The dielectric layer 232 may include an insulating material having a high dielectric constant (e.g., greater than approximately 3.9, among other examples) and/or a high thermal conductivity (e.g., approximately equal to or greater than 100 W/mk, among other examples). The high thermal conductivity may enable heat generated by the heater element 228 to propagate into the PCM layer 234 through the dielectric layer 232, and the high dielectric constant enables the dielectric layer 232 to withstand degradation that might otherwise result from the high operating temperatures of the heater element 228. In some implementations, the dielectric layer 232 includes silicon nitride (SiₓN_{y} such as Si₃N₄) and/or another nitride-containing dielectric material. However, other materials may be used for the dielectric layer 232. The dielectric layer 232 may be formed to have a horizontal width that is included in a range of approximately 5 microns to approximately 20 microns. However, other values for the range are within the scope of the present disclosure.

The PCM layer 234 may correspond to the switching material of the RF switch structure 222. The phase of the PCM layer 234 may be switched to selectively permit the propagation of an RF signal from the RF in electrode 224 to the RF out electrode 226 through the PCM layer 234. Thus, the PCM layer 234 functions as the channel of the RF switch structure 222. The PCM layer 234 may be formed to have a horizontal width such that the PCM layer 234 extends continuously between the RF in electrode 224 and the RF out electrode 226.

As shown in FIG. 2B, the PCM layer 234 may include a portion that is in direct contact with and/or overlaps at least a portion of the RF in electrode 224. Additionally, or alternatively, the PCM layer 234 may include a portion that is in direct contact with and/or overlaps at least a portion of the RF out electrode 226. Additionally, or alternatively, the PCM layer 234 may include a portion that is in direct contact with the dielectric layer 232.

In some implementations, a portion of the PCM layer 234 overlapping the RF in electrode 224 and a portion of the PCM layer 234 overlapping the RF out electrode 226 have a same size and/or width (e.g., the portions overlap same amounts of the PCM layer 234). In some implementations, a portion of the PCM layer 234 overlapping the RF in electrode 224 and a portion of the PCM layer 234 overlapping the RF out electrode 226 have different sizes and or widths (e.g., the portions overlap different amounts of the PCM layer 234).

In some implementations, and as shown in FIG. 2B, the PCM layer 234 includes abrupt transitions (e.g., stepped portions) that enable the dielectric layer 232 to be between the PCM layer 234 and the heater element 228. However, other transitions (e.g., angled transitions and/or curved transitions) may be included in the PCM layer 234 to provide a similar effect (e.g., enable the dielectric layer 232 to be between the PCM layer 234 and the heater element 228).

In some implementations, a thickness D2 of the PCM layer 234 is included in a range of approximately 500 angstroms to approximately 1500 angstroms. If the thickness D2 is less approximately 500 angstroms, a resistivity of the RF switch structure 222 may not satisfy an FOM performance threshold of a semiconductor device including the RF switch structure 222 (e.g., the semiconductor device 200). If the thickness is greater than approximately 500 angstroms, and less than approximately 1500 angstroms, a resistivity may be such that the FOM performance threshold is satisfied and thermal strains and/or stresses within the RF switch structure 222 may be limited such that a cycling endurance of the RF switch structure 222 is extended. If the thickness D2 is greater than approximately 1500 angstroms, thermal strains and/or stresses within the RF switch structure 222 may not be limited and the cycling endurance of RF switch structure 222 may be reduced. However, other values and ranges for the thickness D1 are within the scope of the present disclosure.

Additionally, or alternatively, a width D3 of the PCM layer is included in a range of approximately of approximately 0.5 μm to approximately 3.0 μm. However, other values and ranges for the width D3 are within the scope of the present disclosure.

The PCM layer 234 includes one or more materials that are capable of transitioning between two or more material phases or crystal structure phases. In particular, the PCM layer 234 includes one or more materials that are capable of transitioning between a crystalline phase (or crystalline material structure) and an amorphous phase (or non-crystalline material structure). An example of a material included in the PCM layer 234 is a binary chalcogenides material such as germanium tellurium (GeTe), where a composition range of the PCM layer 234 (e.g., molar percentages of the germanium (Ge) and tellurium (Te)) corresponds to Ge₁₀₀₋ₓTeₓ.

In some implementations, a molar percentage of the tellurium in the PCM layer 234 is greater than a molar percentage of germanium. For example, the molar percentage of tellurium may be greater than or equal to approximately 51%. If the molar percentage of tellurium is less than approximately 51%, a resistivity of the RF switch structure 222 may not satisfy an FOM performance threshold of a semiconductor device including the RF switch structure 222 (e.g., the semiconductor device 200). If the molar percentage of tellurium is greater than or equal to approximately 51%, a resistivity of the PCM layer 234 may satisfy the FOM threshold. However, other values and ranges for the molar percentage of tellurium are within the scope of the present disclosure.

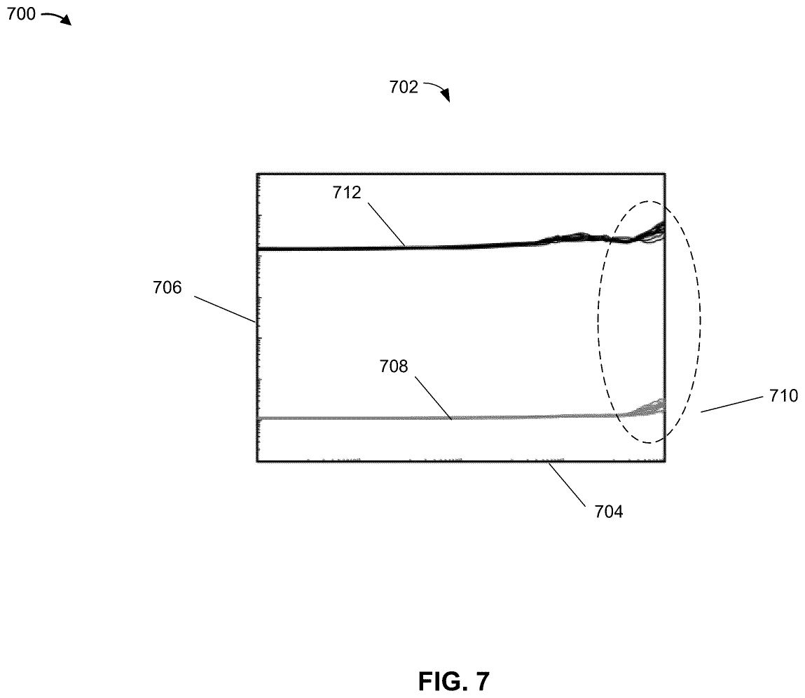

Additionally, or alternatively and in some implementations, a molar percentage of germanium in the PCM layer 234 is included in a range of approximately 43% to approximately 47%. If the molar percentage of germanium is less than approximately 43%, a resistivity of the PCM layer 234 may increase to not satisfy the FOM threshold. If the molar percentage is greater than approximately 43%, and less than approximately 47%, the resistivity of the PCM layer 234 may satisfy the FOM threshold and, as described in greater detail in connection with FIG. 7, clustering of the germanium during cycling may be reduced to avoid thermal strains and/or stresses and extend a cycling duration of the RF switch structure 222. If the molar percentage is greater than approximately 47%, clustering of germanium may occur during cycling to introduce thermal strains and/or stresses to reduce the cycling endurance of the RF switch structure 222. However, other values and ranges for the molar percentage of germanium are within the scope of the present disclosure.

Additionally, or alternatively and in some implementations, a sheet resistance of the PCM layer 234 is included in a range of approximately 18 ohms per square (Ω/sq) to approximately 22 Ω/sq. If the sheet resistance is less than approximately 18 Ω/sq, a material included in PCM layer 234 may not have a crystalline structure that is useable for the RF switch structure 222. If the sheet resistance is between approximately 18 Ω/sq and approximately 22 Ω/sq, the material included in the PCM layer 234 may have a crystalline structure that is useable for the RF switch structure 222 and provide a resistivity that satisfies the FOM threshold. If the sheet resistance is greater than approximately 22 Ω/sq, the RF switch structure 222 may not satisfy the FOM threshold. However, other values and ranges for the sheet resistance are within the scope of the present disclosure.

A dielectric layer 236 (e.g., a capping layer) may be on and/or over the PCM layer 234. The dielectric layer 236 may protect the PCM layer 234 from contamination. Moreover, the dielectric layer 236 may be used as a hard mask layer during manufacturing of the RF switch structure 222. The dielectric layer 236 may include a nitride-containing dielectric material such as a silicon nitride (SiₓN_{y} such as Si₃N₄) among other examples.

As shown in FIG. 2B, the RF switch structure 222 further includes a heat spreader component 238 that is below the heater element 228. The heat spreader component 238 may include a material such as copper (Cu), an aluminum copper alloy (AlCu), gold (Au), or tungsten (W), among other examples. In some implementations, a thickness D4 of the heat spreader component 238 greater than or equal to approximately 1000 angstroms. If the thickness D4 is less than approximately 1000 angstroms, the heat spreader component 238 may not provide a thermal control and/or heat transfer performance (e.g., reduce thermal stresses and/or strains) that is sufficient to improve a cycling endurance of the RF switch structure 222. If the thickness D4 is greater than or equal to approximately 1000 angstroms, the thermal control and/or the heat transfer performance provided by the heat spreader component 238 may be sufficient to improve a cycling endurance of RF switch structure 222. However, other values and ranges for the thickness D4 are within the scope of the present disclosure.

FIG. 2C shows a detailed top plan view of the RF switch structure 222 (e.g., the top plan view using reference perspective V1 of FIG. 2B). Components shown in FIG. 2C include the RF in electrode 224, the RF out electrode 226, the heater element 228, the PCM layer 234, and the heat spreader component 238. In FIG. 2C, the dielectric layer 216, ESLs 218, dielectric fill layer 230, and dielectric layer 236 are omitted for clarity.

As shown in FIG. 2C, the PCM layer 234, the RF in electrode 224, the RF out electrode 226 include a same length D5. As an example, the length D5 may be included in a range of approximately 5 microns (μm) to approximately 25 μm. Alternatively, and in some implementations, the PCM layer 234, the RF in electrode 224, and/or the RF out electrode 226 may include different lengths. However, other values, ranges, and combinations for the length D5 are within the scope of the present disclosure.

As further shown in FIG. 2C, the heat spreader component 238 includes a length D6. As an example, the length D6 may be included in a range of approximately 5 μm to 30 μm. In some implementations, the length D6 is greater than or equal to the length D5. Alternatively, and in some implementations, the length D6 is less than the length D5. However, other values and ranges for the length D6 are within the scope of the present disclosure.

Increasing the length D6 to be greater than or equal to the length D5 increases a planar area of the heat spreader component 238 to increase heat transfer performance of the heat spreader component 238 and further improve a cycling endurance of the RF switch structure 222. Additionally, or alternatively, increasing the length D6 to be greater than or equal to the length D5 may extend ends of the heat spreader component 238 beyond a footprint of the PCM layer 234 to provide at least a portion of heat transfer path (e.g., a thermal conduction path) that excludes the PCM layer 234.

As further shown in FIG. 2C, end portions of the heater element 228 are separated by a distance D7. As an example, the distance D7 may be included in a range of approximately 5 μm to 30 μm. Further, and in some implementations, the length D6 is less than or equal to the distance D7. However, other values and ranges for the distance D7 are within the scope of the present disclosure.

FIG. 2D shows a detailed bottom plan view of the RF switch structure 222 (e.g., the bottom plan view V2 of FIG. 2B). Components shown in FIG. 2D include the RF in electrode 224, the RF out electrode 226, the heater element 228, the PCM layer 234, and the heat spreader component 238. In FIG. 2D the dielectric layer 216, ESLs 218, dielectric fill layer 230, and dielectric layer 236 are omitted for clarity.

As further shown in FIG. 2D, the heat spreader component 238 includes a width D8. In some implementations, the width D8 is included in a range of approximately 0.5 μm to 3 μm. However, other values and ranges for the width D8 are within the scope of the present disclosure. Further, and in some implementations, the width D8 is greater than or equal to the width D1.

In some implementations, and as described in connection with FIGS. 2A-2D, a switch structure (e.g., the RF switch structure 222) includes a first electrode (e.g., the RF in electrode 224). The switch structure includes a second electrode (e.g., the RF out electrode 226) separate from the first electrode. The switch structure includes a phase change material layer (e.g., the PCM layer 234) that connects the first electrode and the second electrode, where the phase change material layer has a first length (e.g., the length D5) along a lateral direction. The switch structure includes a heater element (e.g., the heater element 228) below the phase change material layer. The switch structure includes a heat spreader component (e.g., the heat spreader component 238) below the heater element, where the heat spreader component has a second length (e.g., the length D6) that is along a direction that is approximately parallel to the lateral direction and is greater than or equal to the first length.

Additionally, or alternatively and as described in connection with FIGS. 2A-2D, a semiconductor device (e.g., the semiconductor device 200) includes a semiconductor substrate (e.g., the substrate 210). The semiconductor device includes a backend region (e.g., the backend region 208) above the semiconductor substrate. The semiconductor device includes a switch structure (e.g., the RF switch structure 222) in the backend region. The switch structure includes an input electrode (e.g., the RF in electrode 224) and an output electrode (e.g., the RF out electrode 226). The switch structure includes a heater element (e.g., the heater element 228) between the input electrode and the output electrode. The switch structure includes a phase change material layer (e.g., PCM layer 234) above the heater element that connects the input electrode and the output electrode, where the phase change material layer includes a composition of tellurium and germanium, and where a molar percentage of the tellurium is greater than a molar percentage of the germanium.

In this way, cycling endurance and FOM performances of the switch structure are increased relative to other switch structures. By increasing the cycling endurance and FOM performances, the semiconductor device may satisfy performance thresholds and have a reliability that reduces an amount of resources (e.g., raw materials, semiconductor processing equipment, labor, and/or computing resources) needed to service a high performance market using the semiconductor device.

As indicated above, FIGS. 2A-2D are provided as an example. Other examples may differ from what is described with regard to FIGS. 2A-2D.

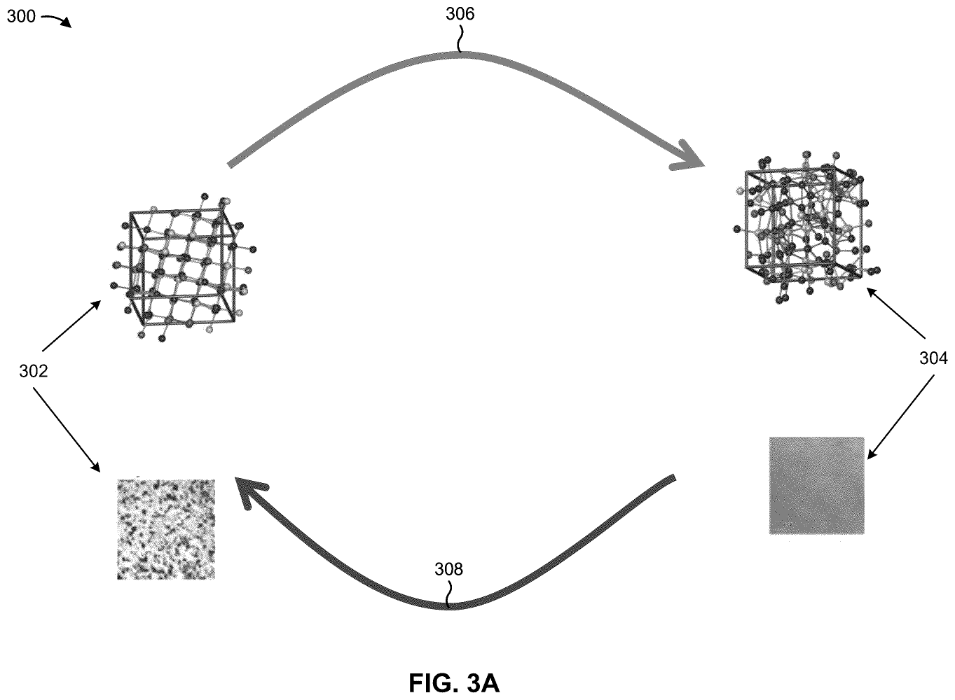

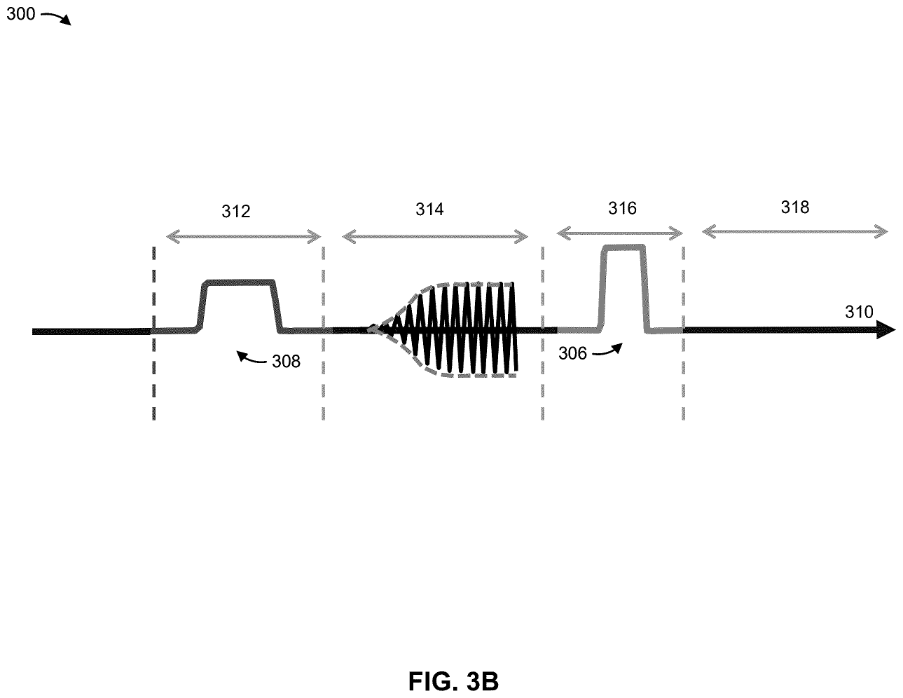

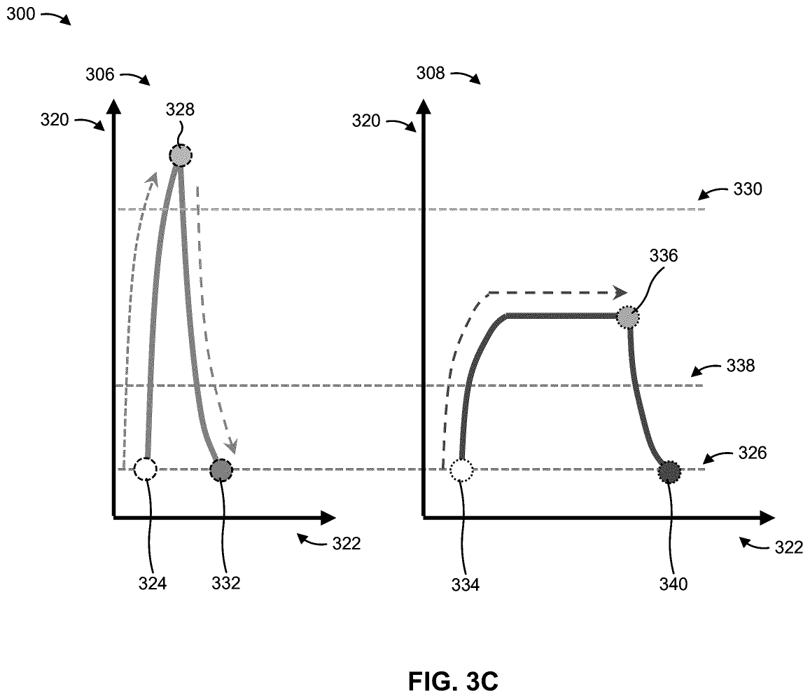

FIGS. 3A-3C are diagrams of example implementations 300 of the operation of a radio frequency switch structure (e.g., the RF switch structure 222) described herein.

As shown in FIG. 3A, the PCM layer 234 of the RF switch structure 222 may be transitioned between a crystalline phase 302 and an amorphous phase 304. In the crystalline phase 302, the material structure of the PCM layer 234 is arranged in an ordered and approximately crystalline structure. In the amorphous phase 304, the material structure of the PCM layer 234 is non-crystalline and/or disordered. The crystalline phase 302 may correspond to the on state of the RF switch structure 222. In the crystalline phase 302, the PCM layer 234 has relatively low resistivity (e.g., relative to the resistivity in the off state), which enables RF signals to propagate through the PCM layer 234. The amorphous phase 304 may correspond to the off state of the RF switch structure 222. In the amorphous phase 304, the PCM layer 234 has relatively high resistivity (e.g., relative to the resistivity in the on state), which prevents RF signals from propagating through the PCM layer 234 between the RF in electrode 224 (e.g., an input electrode) and the RF out electrode 226 (an output electrode).

As further shown in FIG. 3A, a reset operation 306 may be performed to transition the PCM layer 234 from the crystalline phase 302 to the amorphous phase 304. A set operation 308 may be performed to transition the PCM layer 234 from the amorphous phase 304 to the crystalline phase 302. The reset operation 306 and the set operation 308 may each include providing a current (Iₕₑₐₜₑᵣ) to the heater element 228 to cause the heater element 228 to heat (increase the temperature of) the PCM layer 234 to a particular temperature and for a particular time duration.

As shown in FIG. 3B, the set operation 308 may be performed for a transition period 312 along a timeline 310 to transition the RF switch structure 222 to the on state. In the on state, RF signals may propagate through the PCM layer 234 from the RF in electrode 224 to the RF out electrode 226. In an example use case, an RF signal may propagate from a modem of a wireless communication device to an antenna of the wireless communication device through the RF switch structure 222 during a signal transmission period 314 so that the RF signal may be wirelessly transmitted. Subsequently, the reset operation 306 may be performed for a transition period 316 to transition the RF switch structure 222 from the on state to the off state. In the off state, the PCM layer 234 blocks the propagation of RF signals between the RF in electrode 224 to the RF out electrode 226 for an off duration 318.

FIG. 3C illustrates example temperature profiles for the reset operation 306 and for the set operation 308. The temperature profiles are illustrated as a function of the temperature 320 of the PCM layer 234 and time 322.

In the temperature profile for the reset operation 306, the temperature 320 of the PCM layer 234 may be at a starting temperature 324, which may correspond to a baseline temperature 326 (e.g., room temperature or a baseline operating temperature of the RF switch structure 222 with the heater element 228 off). The heater element 228 is subsequently activated by providing a current to the heater element 228, which causes the heater element 228 to generate heat and increase in temperature. The heat generated by the heater element 228 causes the temperature 320 of the PCM layer 234 to also increase from the starting temperature 324.

In the reset operation 306, the temperature 320 of the PCM layer 234 is quickly and rapidly increases to a reset temperature 328. The reset temperature 328 is greater than a melting temperature 330 of the PCM layer 234. Heating the PCM layer 234 such that the temperature 320 of the PCM layer 234 increases to greater than the melting temperature 330 of the PCM layer 234 causes the material of the PCM layer 234 to melt. An example of the melting temperature 330 may be approximately 1000 degrees kelvin. However, other values for the melting temperature 330 are within the scope of the present disclosure.

The heater element 228 is subsequently deactivated, and the material of the PCM layer 234 is quenched such that the temperature 320 of the PCM layer 234 rapidly decreases back to an ending temperature 332 corresponding to the baseline temperature 326. The rapid heating (above the melting temperature 330) and cooling of the PCM layer 234 causes the material of the PCM layer 234 to transition from the crystalline phase 302 to the amorphous phase 304.

In the temperature profile for the set operation 308, the temperature 320 of the PCM layer 234 may be at a starting temperature 334, which may correspond to a baseline temperature 326 (e.g., room temperature or a baseline operating temperature of the RF switch structure 222 with the heater element 228 off). The heater element 228 is subsequently activated by providing a current to the heater element 228, which causes the heater element 228 to generate heat and increase in temperature. The heat generated by the heater element 228 causes the temperature 320 of the PCM layer 234 to also increase from the starting temperature 334.

In the set operation 308, the temperature 320 of the PCM layer 234 is increased to and maintained at a set temperature 336. The PCM layer 234 is maintained at the set temperature 336 for a greater time duration than the reset temperature 328. For example, the time duration of the set operation 308 may be on the order of a few microseconds (e.g., 1-5 microsections), whereas the time duration of the reset operation 306 may be on the order of nanoseconds (e.g., 100-200 nanoseconds). The set temperature 336 is less than the reset temperature 328. In particular, the set temperature 336 is greater than a crystallization temperature 338 of the material of the PCM layer 234 and less than the melting temperature 330 of the material of the PCM layer 234. An example of the crystallization temperature 338 may be approximately 500 degrees kelvin. However, other values for the crystallization temperature 338 are within the scope of the present disclosure. A greater voltage magnitude may be applied to the heater element 228 to heat the PCM layer 234 to a greater temperature in the reset operation 306 relative to the voltage magnitude that is applied to the heater element 228 to heat the PCM layer 234 in the set operation 308.

Heating the PCM layer 234 such that the temperature 320 of the PCM layer 234 increases to greater than the crystallization temperature 338 and less than the melting temperature 330 causes the material of the PCM layer 234 to crystalize (or recrystallize), which causes the material of the PCM layer 234 to transition from the amorphous phase 304 to the crystalline phase 302. The heater element 228 is subsequently deactivated, and the material of the PCM layer 234 is quenched such that the temperature 320 of the PCM layer 234 decreases to an ending temperature 340 that corresponds to the baseline temperature 326.

As indicated above, FIGS. 3A-3C are provided as examples. Other examples may differ from what is described with regard to FIGS. 3A-3C.

FIGS. 4A-4E are diagrams of an example implementation 400 of forming a semiconductor device 200 described herein. In some implementations, one or more of the semiconductor processing tools 102-112 and/or the wafer/die transport tool 114 may be used to perform one or more of the semiconductor processing operations described in connection with FIGS. 4A-4E. In some implementations, one or more of the semiconductor processing operations described in connection with FIGS. 4A-4E may be performed using another semiconductor processing tool.

Turning to FIG. 4A, the substrate 210 is provided. The substrate 210 may be provided in the form of a semiconductor wafer such as a silicon (Si) wafer, a silicon on insulator (SOI) wafer, and/or another type of semiconductor workpiece.

As shown in FIG. 4B, the active devices 212 may be formed in and/or on the substrate 210 in the frontend region 206 of the semiconductor device 200. The active devices 212 are formed in the logic portion 202 of the semiconductor device 200 and, in some implementations, also in the RF portion 204 of the semiconductor device 200. Alternatively, the active devices 212 may be omitted from the RF portion 204 of the semiconductor device 200.

One or more of the semiconductor processing tools 102-114 may be used to form one or more portions of the active devices 212. For example, a deposition tool 102 may be used to perform various deposition operations to deposit layers of the active devices 212, and/or to deposit photoresist layers for etching the substrate 210 and/or portions of the deposited layers. As another example, an exposure tool 104 may be used to expose the photoresist layers to form patterns in the photoresist layers. As another example, a developer tool 106 may develop the patterns in the photoresist layers. As another example, an etch tool 108 may be used to etch the substrate 210 and/or portions of the deposited layers to form the active devices 212. As another example, a planarization tool 110 may be used to planarize portions of the active devices 212. As another example, a plating tool 112 may be used to deposit metal structures and/or layers of the active devices 212.

As shown in FIG. 4C, a deposition tool 102 is used to deposit the dielectric layer 214 over and/or on the substrate 210 and over and/or on the active devices 212. A first portion of the backend region 208 of the semiconductor device 200 is then formed over the dielectric layer 214. A deposition tool 102 is used to deposit alternating layers of ESLs 218 and dielectric layers 216 of the first portion of the backend region 208 of the semiconductor device 200. A deposition tool 102, an exposure tool 104, a developer tool 106, an etch tool 108, a planarization tool 110, and/or a plating tool 112 are used to perform various operations to form the metallization layers 220 in the first portion of the backend region 208 of the semiconductor device 200. The metallization layers 220 may be included in the dielectric layers 216 and/or the ESLs 218, and may be electrically coupled with the active devices 212 in the frontend region 206.

As shown in FIG. 4D, a second portion of the backend region 208 of the semiconductor device 200 is then formed over the first portion of the backend region 208. A deposition tool 102 is used to deposit alternating layers of ESLs 218 and dielectric layers 216 of the second portion of the backend region 208 of the semiconductor device 200. A deposition tool 102, an exposure tool 104, a developer tool 106, an etch tool 108, a planarization tool 110, and/or a plating tool 112 are used to perform various operations to form the metallization layers 220 in the second portion of the backend region 208 of the semiconductor device 200. The metallization layers 220 may be included in the dielectric layers 216 and/or the ESLs 218.

As shown in FIG. 4E, the RF switch structure 222 is formed in the RF portion 204 of the backend region 208 and electrically coupled and/or physically coupled to one or more metallization layers 220 in the backend region 208. The RF switch structure 222 may be formed in a dielectric layer 216 of the backend region 208. An example implementation of forming the RF switch structure 222 is described in connection with FIGS. 5A-5M.

As indicated above, FIGS. 4A-4E are provided as examples. Other examples may differ from what is described with regard to FIGS. 4A-4E.

FIGS. 5A-5M are diagrams of an example implementation 500 of forming the RF switch structure 222 described herein described herein. The RF switch structure 222 is formed in the RF portion 204 of the semiconductor device 200. In some implementations, one or more of the semiconductor processing tools 102-112 and/or the wafer/die transport tool 114 may be used to perform one or more of the semiconductor processing operations described in connection with FIGS. 5A-5M. In some implementations, one or more of the semiconductor processing operations described in connection with FIGS. 5A-5M may be performed using another semiconductor processing tool.

Turning to FIG. 5A, a dielectric layer 216 (e.g., of the backend region 208 of the semiconductor device 200) may be formed, as described in connection with FIGS. 4A-4E.

As shown in FIG. 5B, a cavity 502 is formed in the dielectric layer 216. In some implementations, a pattern in a photoresist layer is used to etch the dielectric layer 216 to form the cavity 502. In these implementations, the deposition tool 102 may be used to form the photoresist layer on the dielectric layer 216. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric layer 216 based on the pattern to form the cavity 502 in the dielectric layer 216. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 216 based on a pattern.

As shown in FIG. 5C, the heat spreader component 238 is formed in the dielectric layer 216 (e.g., the cavity 502). The deposition tool 102 and/or the plating tool 112 may be used to deposit the heat spreader component 238 in a CVD operation, a PVD operation, an ALD operation, an electroplating operation, another deposition operation described above in connection with FIG. 1, and/or another suitable deposition operation. In some implementations, a seed layer is first deposited, and the heat spreader component 238 is deposited on the seed layer. In some implementations, the planarization tool 110 may be used to planarize the heat spreader component 238 after the heat spreader component 238 is deposited.

As shown in FIG. 5D, the ESL 218 and the dielectric fill layer 230 are formed on and/or over the dielectric layer 216 and/or heat spreader component 238. The deposition tool 102 may be used to deposit the dielectric layer 216 and/or the dielectric fill layer 230 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the dielectric layer 216 and/or the 230 after the dielectric layer 216 and/or the dielectric fill layer 230 is deposited.

As shown in FIG. 5E, cavities 504 are formed in the dielectric fill layer 230. In some implementations, a pattern in a photoresist layer is used to etch the dielectric fill layer 230 to form the cavities 504. In these implementations, the deposition tool 102 may be used to form the photoresist layer on the dielectric fill layer 230. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric fill layer 230 based on the pattern to form the cavities 504 in the dielectric fill layer 230. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric fill layer 230 based on a pattern.

As shown in FIG. 5F, the RF in electrode 224 and the RF out electrode 226 are formed in the dielectric fill layer 230 (e.g., in the cavities 504). The deposition tool 102 and/or the plating tool 112 may be used to deposit the RF in electrode 224 and the 226 in a CVD operation, a PVD operation, an ALD operation, an electroplating operation, another deposition operation described above in connection with FIG. 1, and/or another suitable deposition operation. In some implementations, a seed layer is first deposited, and the RF in electrode 224 and/or the RF out electrode 226 is deposited on the seed layer. In some implementations, the planarization tool 110 may be used to planarize the RF in electrode 224 and/or the RF out electrode 226 after the RF in electrode 224 and/or the RF out electrode 226 is deposited.

As shown in FIG. 5G, a cavity 506 is formed in the dielectric fill layer 230. In some implementations, a pattern in a photoresist layer is used to etch the dielectric fill layer 230 to form the cavity 506. In these implementations, the deposition tool 102 may be used to form the photoresist layer on the dielectric fill layer 230. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric fill layer 230 based on the pattern to form the cavity 506 in the dielectric fill layer 230. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric fill layer 230 based on a pattern.

As shown in FIG. 5H, the heater element 228 is formed in the dielectric fill layer 230 (e.g., the cavity 506). The deposition tool 102 and/or the plating tool 112 may be used to deposit the heater element 228 in a CVD operation, a PVD operation, an ALD operation, an electroplating operation, another deposition operation described above in connection with FIG. 1, and/or another suitable deposition operation. In some implementations, a seed layer is first deposited, and the heater element 228 is deposited on the seed layer. In some implementations, the planarization tool 110 may be used to planarize the heater element 228 after the heater element 228 is deposited.

As shown in FIG. 5I, the dielectric layer 232 is formed on and/or over the RF in electrode 224, the RF out electrode 226, the heater element 228, and/or the dielectric fill layer 230. The deposition tool 102 may be used to deposit the dielectric layer 232 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the dielectric layer 232 after the dielectric layer 232 is deposited.

As shown in FIG. 5J, cavities 508 are formed in the dielectric layer 232 to expose the RF in electrode 224 and/or the RF out electrode 226. In some implementations, a pattern in a photoresist layer is used to etch the dielectric layer 232 to form the cavities 508. In these implementations, the deposition tool 102 may be used to form the photoresist layer on the dielectric layer 232. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric layer 232 based on the pattern to form the cavities 508 in the dielectric layer 232. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 232 based on a pattern.

As shown in FIG. 5K, the PCM layer 234 is formed on and/or over the RF in electrode 224, the RF out electrode 226, and/or the dielectric layer 232. Forming the PCM layer 234 may connect the RF in electrode 224 and the RF out electrode 226. The deposition tool 102 may be used to deposit the PCM layer 234 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the PCM layer 234 after the PCM layer 234 is deposited.

As shown in FIG. 5L, cavities 510 are formed in the PCM layer 234. In some implementations, a pattern in a photoresist layer is used to etch the PCM layer 234 to form the cavities 510. In these implementations, the deposition tool 102 may be used to form the photoresist layer on the PCM layer 234. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the PCM layer 234 based on the pattern to form the cavities 510 in the PCM layer 234. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the PCM layer 234 based on a pattern.

As shown in FIG. 5M, the dielectric layer 236 is formed on and/or over the RF in electrode 224, the RF out electrode 226, and/or the PCM layer 234. The deposition tool 102 may be used to deposit the dielectric layer 236 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the dielectric layer 236 after the dielectric layer 236 is deposited.

As indicated above, FIGS. 5A-5M are provided as an example. Other examples may differ from what is described with regard to FIGS. 5A-5M.

Different combinations of materials and/or operations as described in connection with FIGS. 2A-2D, FIGS. 5A-5M, and elsewhere herein may be used to implement variations the RF switch structure 222. For example, and in some implementations, the RF in electrode 224, the RF out electrode 226, and the heater element 228 may use a same material, enabling a common deposition operation to reduce a number of operations used to form the RF switch structure 222.

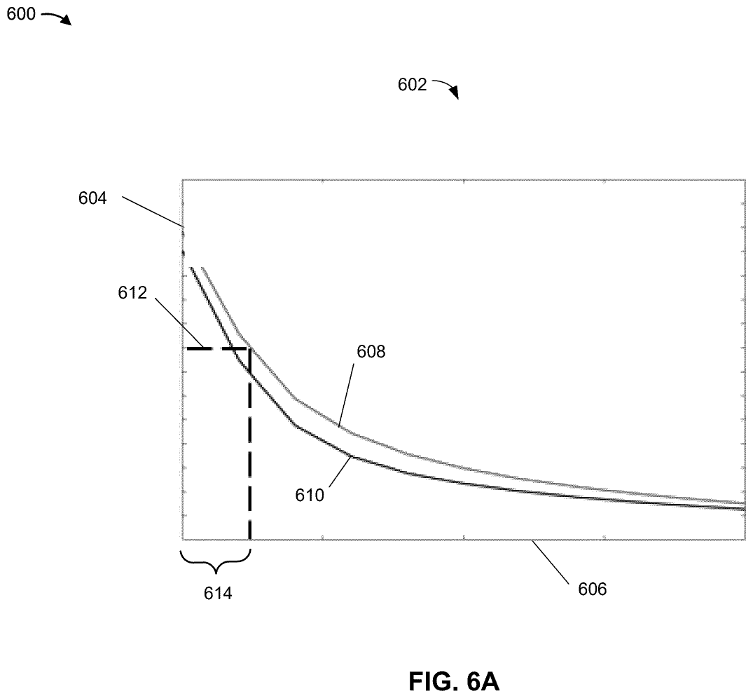

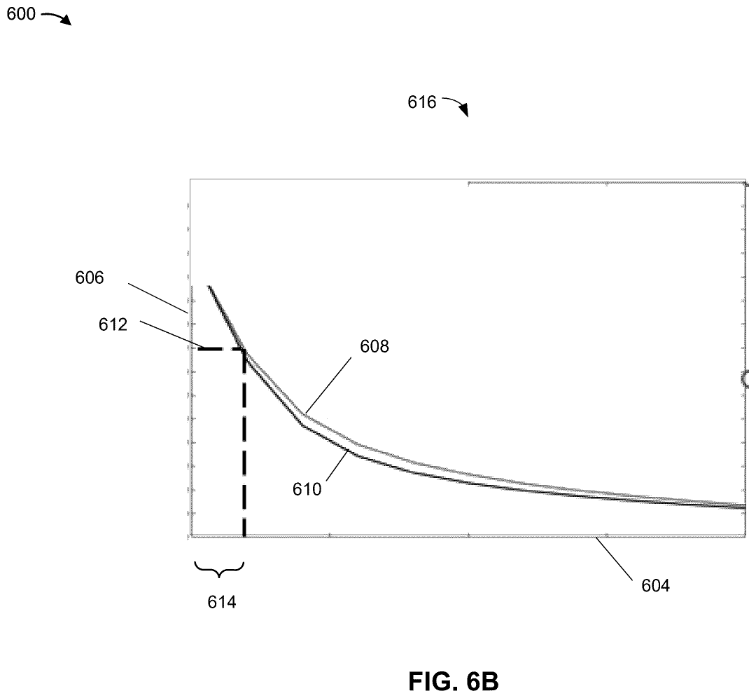

FIGS. 6A and 6B are diagrams of example data related to an implementation 600 of a radio frequency switch structure (e.g., the RF switch structure 222) described herein. As shown in FIGS. 6A and 6B, the data relates to a quench performance of the radio frequency switch structure as described in connection with FIGS. 3A-3C.

As shown in FIG. 6A, example data 602 may correspond to a quench performance of a configuration of the radio frequency switch structure, where a length of a heat spreader component (e.g., the length D6 of the heat spreader component 238) is approximately equal to a length of a PCM layer (e.g., the length D5 of the PCM layer 234). Data 602 includes a temperature 604 (e.g., a temperature in degrees Celsius (C)) plotted against time 606 (e.g., a time in nanoseconds).

Data 602 includes the temperature 604 at or near an edge 608 of the radio frequency switch structure and the temperature 604 at or near a center 610 of the radio frequency switch structure. As an example, for a target temperature 612 (e.g., a target quenching or cooling temperature) of approximately 500° C., a quench duration 614 may be approximately 50 nanoseconds. For the radio frequency switch structure associated with data 602, a cycling endurance may exceed approximately 1 billion cycles.

As shown in FIG. 6B, example data 616 may correspond to a quench performance of a configuration of the radio frequency switch structure, where a length of a heat spreader component (e.g., the length D6 of the heat spreader component 238) is approximately greater than a length of a PCM layer (e.g., the length D5 of the PCM layer 234). In contrast to the example 602, the quench duration 614 may be approximately 25 nanoseconds. The cycling endurance of the radio frequency switch structure associated with data 616 may be increased relative to the cycling endurance of the radio frequency switch structure associated with data 602.

FIGS. 6A and 6B are provided as one or more examples. Other examples, including target temperatures and/or quench durations, may differ from what is described with regard to FIGS. 6A and 6B.

FIG. 7 is a diagram of example data related to an implementation 700 of a radio frequency switch structure (e.g., the RF switch structure 222) described herein. As shown in FIG. 7, example data 702 relates to resistivity characteristics of the radio frequency switch structure, where a material included in a PCM layer (e.g., the PCM layer 234) includes a phase change material having a 45% molar concentration of germanium and a 55% molar concentration of tellurium (Ge₄₅Te₅₅).

Data 702 includes a number of cycles 704 versus a resistance 706 (e.g., a resistance in ohms) of the PCM layer at approximately 0.1 volts. In a region 710 corresponding to an end of a cycling endurance, a dispersion and/or a variation of resistances associated with a low resistance state (LRS) 708 and/or a high resistance state (HRS) 712 is contained due to a lack of clustering of germanium within the PCM layer.

FIG. 7 is provided as an example. Other examples may differ from what is described with regard to FIG. 7.

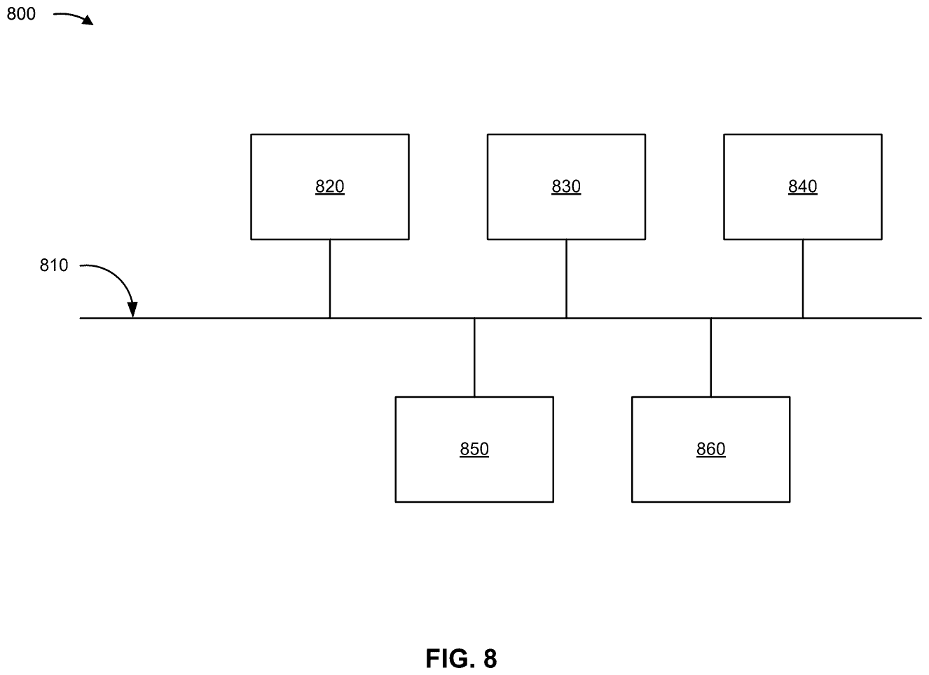

FIG. 8 is a diagram of example components of a device 800 described herein. In some implementations, one or more of the semiconductor processing tools 102-112 and/or the wafer/die transport tool 114 may include one or more devices 800 and/or one or more components of the device 800. As shown in FIG. 8, the device 800 may include a bus 810, a processor 820, a memory 830, an input component 840, an output component 850, and/or a communication component 860.

The bus 810 may include one or more components that enable wired and/or wireless communication among the components of the device 800. The bus 810 may couple together two or more components of FIG. 8, such as via operative coupling, communicative coupling, electronic coupling, and/or electric coupling. For example, the bus 810 may include an electrical connection (e.g., a wire, a trace, and/or a lead) and/or a wireless bus. The processor 820 may include a central processing unit, a graphics processing unit, a microprocessor, a controller, a microcontroller, a digital signal processor, a field-programmable gate array, an application-specific integrated circuit, and/or another type of processing component. The processor 820 may be implemented in hardware, firmware, or a combination of hardware and software. In some implementations, the processor 820 may include one or more processors capable of being programmed to perform one or more operations or processes described elsewhere herein.

The memory 830 may include volatile and/or nonvolatile memory. For example, the memory 830 may include random access memory (RAM), read only memory (ROM), a hard disk drive, and/or another type of memory (e.g., a flash memory, a magnetic memory, and/or an optical memory). The memory 830 may include internal memory (e.g., RAM, ROM, or a hard disk drive) and/or removable memory (e.g., removable via a universal serial bus connection). The memory 830 may be a non-transitory computer-readable medium. The memory 830 may store information, one or more instructions, and/or software (e.g., one or more software applications) related to the operation of the device 800. In some implementations, the memory 830 may include one or more memories that are coupled (e.g., communicatively coupled) to one or more processors (e.g., processor 820), such as via the bus 810. Communicative coupling between a processor 820 and a memory 830 may enable the processor 820 to read and/or process information stored in the memory 830 and/or to store information in the memory 830.

The input component 840 may enable the device 800 to receive input, such as user input and/or sensed input. For example, the input component 840 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 850 may enable the device 800 to provide output, such as via a display, a speaker, and/or a light-emitting diode. The communication component 860 may enable the device 800 to communicate with other devices via a wired connection and/or a wireless connection. For example, the communication component 860 may include a receiver, a transmitter, a transceiver, a modem, a network interface card, and/or an antenna.

The device 800 may perform one or more operations or processes described herein. For example, a non-transitory computer-readable medium (e.g., memory 830) may store a set of instructions (e.g., one or more instructions or code) for execution by the processor 820. The processor 820 may execute the set of instructions to perform one or more operations or processes described herein. In some implementations, execution of the set of instructions, by one or more processors 820, causes the one or more processors 820 and/or the device 800 to perform one or more operations or processes described herein. In some implementations, hardwired circuitry may be used instead of or in combination with the instructions to perform one or more operations or processes described herein. Additionally, or alternatively, the processor 820 may be configured to perform one or more operations or processes described herein. Thus, implementations described herein are not limited to any specific combination of hardware circuitry and software.

The number and arrangement of components shown in FIG. 8 are provided as an example. The device 800 may include additional components, fewer components, different components, or differently arranged components than those shown in FIG. 8. Additionally, or alternatively, a set of components (e.g., one or more components) of the device 800 may perform one or more functions described as being performed by another set of components of the device 800.

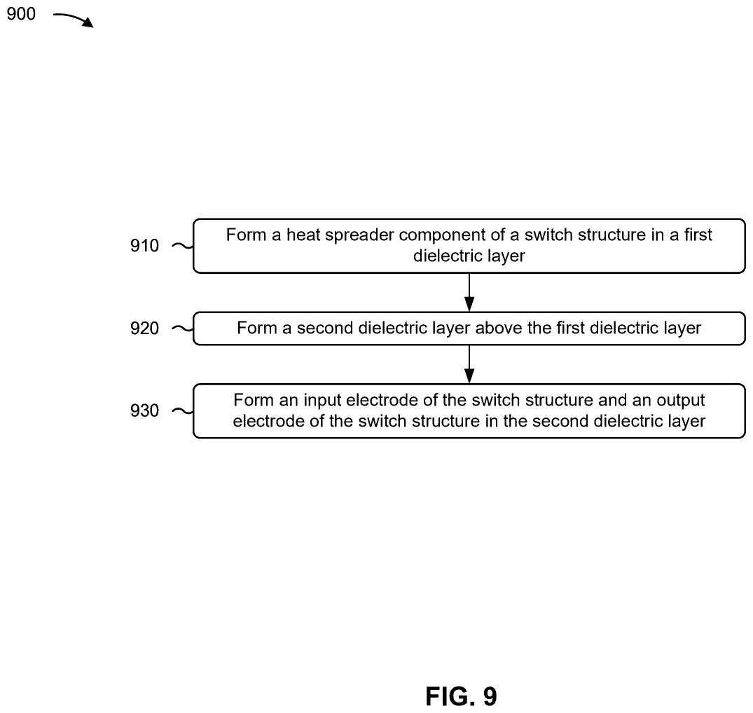

FIG. 9 is a flowchart of an example process 900 associated with forming a semiconductor device described herein. In some implementations, one or more process blocks of FIG. 9 are performed using one or more semiconductor processing tools (e.g., one or more of the semiconductor processing tools 102-112). Additionally, or alternatively, one or more process blocks of FIG. 9 may be performed using one or more components of device 800, such as processor 820, memory 830, input component 840, output component 850, and/or communication component 860.

As shown in FIG. 9, process 900 may include forming a heat spreader component of a switch structure in a first dielectric layer (block 910). For example, one or more of the semiconductor processing tools 102-112 may be used to form a heat spreader component (e.g., the heat spreader component 238) of a switch structure (e.g., the RF switch structure 222) in a first dielectric layer (e.g., the dielectric layer 216), as described herein. In some implementations, the heat spreader component has a first length (e.g., the length D6) along a lateral direction.

As further shown in FIG. 9, process 900 may include forming a second dielectric layer above the first dielectric layer (block 920). For example, one or more of the semiconductor processing tools 102-112 may be used to form a second dielectric layer (e.g., the dielectric fill layer 230) above the first dielectric layer, as described herein.

As further shown in FIG. 9, process 900 may include forming an input electrode of the switch structure and an output electrode of the switch structure in the second dielectric layer (block 930). For example, one or more of the semiconductor processing tools 102-112 may be used to form an input electrode (e.g., the electrode 224) of the switch structure and an output electrode (e.g., the electrode 226) of the switch structure in the second dielectric layer, as described herein. In some implementations, a second length (e.g., the length D5) of the input electrode and the output electrode is along a direction that approximately parallel to the lateral direction and is less than or equal to the first length.

Process 900 may include additional implementations, such as any single

implementation or any combination of implementations described below and/or in connection with one or more other processes described elsewhere herein.

In a first implementation, forming the heat spreader component in the first dielectric layer comprises forming the heat spreader component in a layer of an undoped silicon glass material.

In a second implementation, alone or in combination with the first implementation, process 900 includes forming a heater element (e.g., the heater element 228) of the switch structure in the second dielectric layer between the input electrode and the output electrode, forming a third dielectric layer (e.g., the dielectric layer 232) over the heater element, and forming a phase change material layer (e.g., the PCM layer 234) over the third dielectric layer that connects the input electrode and the output electrode.

In a third implementation, alone or in combination with one or more of the first and second implementations, forming the phase change material layer includes forming the phase change material layer from a binary chalcogenide material.

In a fourth implementation, alone or in combination with one or more of the first through third implementations, forming the phase change material layer includes forming the phase change material layer from a composition that includes germanium and tellurium.

In a fifth implementation, alone or in combination with one or more of the first through fourth implementations, forming the phase change material layer includes forming the phase change material layer to have a thickness (e.g., the thickness D2) that is included in a range of approximately 500 angstroms to approximately 1500 angstroms.

In a sixth implementation, alone or in combination with one or more of the first through fifth implementations, forming the phase change material layer includes forming the phase change material layer from a material having a sheet resistance that is included in a range of approximately 18 ohms per square to approximately 22 ohms per square.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

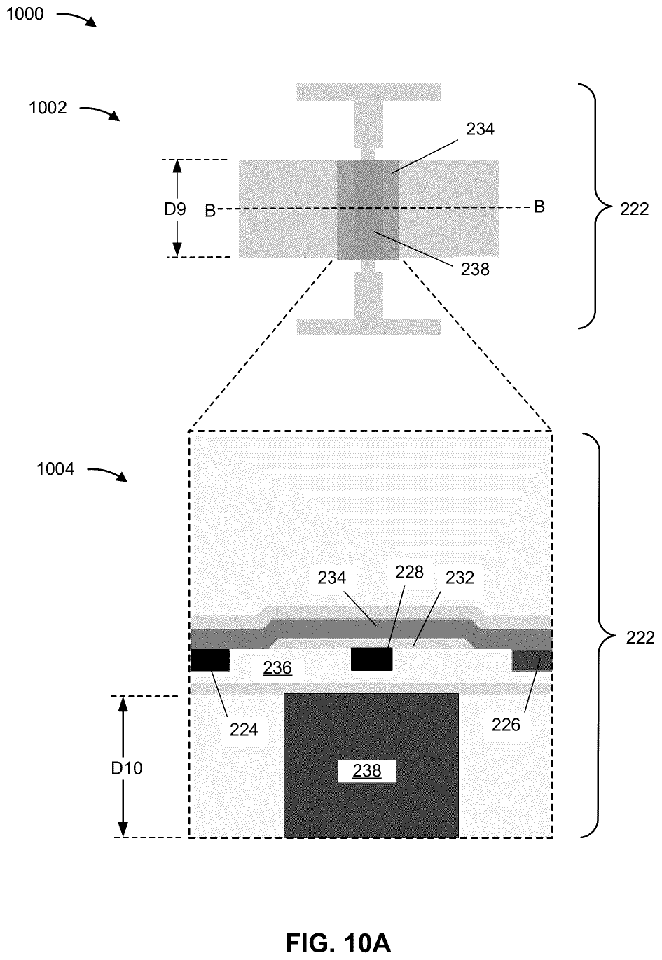

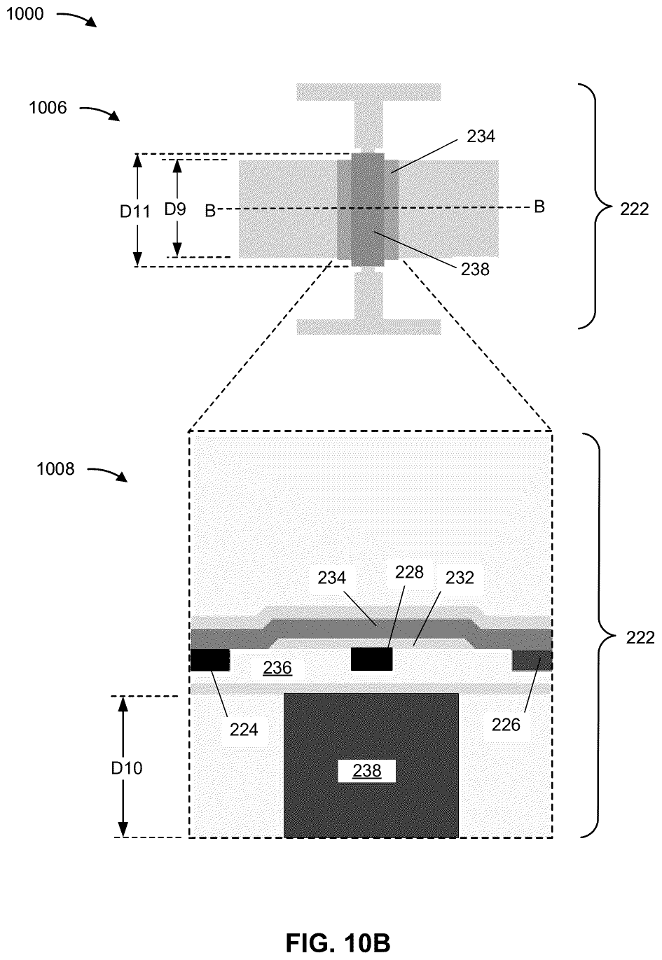

FIGS. 10A and 10B are diagrams of example implementations 1000 of a radio frequency switch structure (e.g., the RF switch structure 222) described herein.

FIG. 10A shows a plan view 1002 and a cross-section side view 1004 of the RF switch structure 222. As shown in plan view 1002, and as described in connection with FIG. 2C, the PCM layer 234 and the heat transfer structure 238 may share a substantially similar length D9.

As shown in cross-section side view 1004, and in contrast to having abrupt transitions (e.g., stepped portions) as described in connection with FIG. 2B and elsewhere herein, the PCM layer 234 includes angled and/or curved transitions. Furthermore, the heat transfer structure 238 includes a thickness D10. In a case where the thickness D10 is approximately 8500 angstroms (and the PCM layer 234 and the heat transfer structure 238 share the substantially similar length D9), a quench performance of the RF switch structure 222 may correspond to the quench performance as described in connection with FIG. 6A.

FIG. 10B shows a plan view 1006 and a cross-section side view 1008 of the RF switch structure 222. As shown in plan view 1006, and in contrast to having abrupt transitions (e.g., stepped portions) as described in connection with FIG. 2B and elsewhere herein, the PCM layer 234 includes angled and/or curved transitions. Furthermore, the PCM layer 234 has the length D9 and the heat transfer structure 238 has a length D11, where the length D11 is substantially greater than the length D9.

Furthermore, and as shown in cross-section side view 1008, the heat transfer structure 238 may have the thickness D10. In a case where the thickness D10 is approximately 8500 angstroms (and the PCM layer 234 has the length D9 and the heat transfer structure 238 has the length D11), a quench performance of the RF switch structure 222 may correspond to the quench performance as described in connection with FIG. 6B.

As indicated above, FIGS. 10A and 10B are provided as one or more examples. Other examples may differ from what is described with regard to FIGS. 10A and 10B.

Some implementations described herein include a semiconductor device. The semiconductor device includes an RF switch structure including a phase change material (PCM) layer and a heat spreader component. A form factor and a location of the heat spreader component improves a uniformity of heat distribution within the RF switch structure relative to other heat spreader components having different form factors and/or locations. Additionally, the PCM layer includes a concentration of germanium and tellurium that reduces a resistivity of the RF switch structure relative to other concentrations.

In this way, cycling endurance and FOM performances of the RF switch structure are increased relative to other RF switch structures. By increasing the cycling endurance and FOM performances, the semiconductor device may satisfy performance thresholds and have a reliability that reduces an amount of resources (e.g., raw materials, semiconductor processing equipment, labor, and/or computing resources) needed to service a high performance market using the semiconductor device.

As described in greater detail above, some implementations described herein provide a switch structure. The switch structure includes a first electrode. The switch structure includes a second electrode separate from the first electrode. The switch structure includes a phase change material layer that connects the first electrode and the second electrode, where the phase change material layer has a first length along a lateral direction. The switch structure includes a heater element below the phase change material layer. The switch structure includes a heat spreader component below the heater element, where the heat spreader component has a second length that is along a direction that is approximately parallel to the lateral direction and that is greater than or equal to the first length.

As described in greater detail above, some implementations described herein provide a semiconductor device. The semiconductor device includes a semiconductor substrate. The semiconductor device includes a backend region above the semiconductor substrate. The semiconductor device includes a switch structure in the backend region. The switch structure includes an input electrode and an output electrode. The switch structure includes a heater element between the input electrode and the output electrode. The switch structure includes a phase change material layer above the heater element that connects the input electrode and the output electrode, where the phase change material layer includes a composition of tellurium and germanium, and where a molar percentage of the tellurium is greater than a molar percentage of the germanium.

As described in greater detail above, some implementations described herein provide a method. The method includes forming a heat spreader component of a switch structure in a first dielectric layer, where the heat spreader component has a first length. The method includes forming a second dielectric layer above the first dielectric layer. The method includes forming an input electrode of the switch structure and an output electrode of the switch structure in the second dielectric layer, where a length of the input electrode and the output electrode is less than or equal to the first length.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A switch structure, comprising:
a first electrode;
a second electrode separate from the first electrode;
a phase change material layer that connects the first electrode and the second electrode,
wherein the phase change material layer has a first length along a lateral direction;
a heater element below the phase change material layer; and
a heat spreader component below the heater element,
wherein the heat spreader component has a second length that is along a direction that is approximately parallel to the lateral direction and that is greater than or equal to the first length.

2. The switch structure of claim 1, wherein the heat spreader component has a thickness that is greater than or equal to approximately 1000 angstroms.

3. The switch structure of claim 1, wherein the second length is less than or equal to a distance between end portions of the heater element.

4. The switch structure of claim 1, wherein a width of the heat spreader component is greater than or equal to a width of a central portion of the heater element.

5. The switch structure of claim 1, wherein the heat spreader component comprises:
copper,
gold,
tungsten, or
an aluminum copper alloy.

6. The switch structure of claim 1, wherein the phase change material layer comprises:
a binary chalcogenides material.

7. The switch structure of claim 6, wherein the binary chalcogenide material comprises:
a composition of germanium and tellurium.

8. A semiconductor device, comprising:
a semiconductor substrate;
a backend region above the semiconductor substrate; and
a switch structure in the backend region and comprising:
an input electrode;
an output electrode;
a heater element between the input electrode and the output electrode; and
a phase change material layer above the heater element that connects the input electrode and the output electrode,
wherein the phase change material layer includes a composition of tellurium and germanium, and
wherein a molar percentage of the tellurium is greater than a molar percentage of the germanium.

9. The semiconductor device of claim 8, wherein the molar percentage of the tellurium is greater than or equal to approximately 51%.

10. The semiconductor device of claim 8, wherein the molar percentage of the germanium is included in a range of approximately 43% to approximately 47%.

11. The semiconductor device of claim 8, further comprising:
a heat spreader component below the heater element.

12. The semiconductor device of claim 11, wherein the heat spreader component is between the input electrode and the output electrode.

13. The semiconductor device of claim 11, further comprising:
at least one dielectric layer between the heat spreader component and the heater element.

14. A method, comprising:
forming a heat spreader component of a switch structure in a first dielectric layer,
wherein the heat spreader component has a first length along a lateral direction;
forming a second dielectric layer above the first dielectric layer; and
forming an input electrode of the switch structure and an output electrode of the switch structure in the second dielectric layer,
wherein a second length of the input electrode and the output electrode that is along a direction that is approximately parallel to the lateral direction is less than or equal to the first length.

15. The method of claim 14, wherein forming the heat spreader component in the first dielectric layer comprises:
forming the heat spreader component in a layer of an undoped silicon glass material.

16. The method of claim 14, further comprising:
forming a heater element of the switch structure in the second dielectric layer between the input electrode and the output electrode,
forming a third dielectric layer over the heater element, and
forming a phase change material layer over the third dielectric layer that connects the input electrode and the output electrode.

17. The method of claim 16, wherein forming the phase change material layer includes:
forming the phase change material layer from a binary chalcogenide material.

18. The method of claim 16, wherein forming the phase change material layer includes:
forming the phase change material layer from a composition that includes germanium and tellurium.

19. The method of claim 16, wherein forming the phase change material layer includes:
forming the phase change material layer to have a thickness that is included in a range of approximately 500 angstroms to approximately 1500 angstroms.

20. The method of claim 16, wherein forming the phase change material layer includes:
forming the phase change material layer from a material having a sheet resistance that is included in a range of approximately 18 ohms per square to approximately 22 ohms per square.
